(19) United States
(12) Patent Application Publication
(10) Pub. No.: US 2025/0133770 A1
(43) Pub. Date: Apr. 24, 2025

(54) SEMICONDUCTOR STRUCTURES FOR MONITORING PLASMA PROCESS-INDUCED DAMAGES

(71) Applicant: Taiwan Semiconductor Manufacturing Company, Ltd., Hsin-Chu (TW)

(72) Inventors: Sze Hang Poon, Hsinchu City (TW); Jun He, Hsinchu County (TW); Hsi-Yu Kuo, Hsinchu City (TW)

(21) Appl. No.: 18/581,058

(22) Filed: Feb. 19, 2024

Related U.S. Application Data
(60) Provisional application No. 63/591,697, filed on Oct. 19, 2023.

(51) Int. Cl. H01L 29/417; H01L 21/768; H01L 23/522; H01L 23/528; H01L 29/06; H01L 29/423; H01L 29/66; H01L 29/775; H01L 29/786

(52) U.S. Cl. CPC H10D 30/6729; H01L 21/76831; H01L 23/5226; H01L 23/5283; H10D 30/014; H10D 30/43; H10D 30/6735; H10D 30/6757; H10D 62/121

(57) ABSTRACT

Semiconductor structures and methods of forming the same are provided. In an embodiment, a method includes forming a first antenna coupled to a gate structure of a transistor, the first antenna comprising a first metal line, forming a second antenna coupled to a source/drain feature of the transistor, the second antenna comprising a second metal line, wherein the first metal line and the second metal line are disposed within a same metallization layer, forming a dielectric layer over the metallization layer, performing a plasma etching process to the dielectric layer, thereby forming first trenches exposing the first metal line and second trenches exposing the second metal line, respectively, wherein the first trenches and second trenches are formed in a chronological order, and forming first and second conductive vias in the first trenches and second trenches, respectively.

### PRIORITY DATA

This application claims priority to U.S. Provisional Patent Application Ser. No. 63/591,697, filed Oct. 19, 2023, the entirety of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Fabrication of IC devices includes front-end-of-line (FEOL) processes and back-end-of-line (BEOL) processes. In general, the FEOL processes form transistors on a substrate and the BEOL processes form interconnect structures over or below the transistors to functionally connect the transistors. The BEOL processes include etching steps that often use plasma. The use of plasma may generate charges that may accumulate at electrically isolated nodes during BEOL processes. When sufficient charges are accumulated, the energy may be dissipated on a single spot of a gate dielectric layer. This may cause breakdown of the gate dielectric layer and permanent damage to the transistor. This kind of damages may be referred to as plasma process-induced damages (PIDs). While existing methods and structures for protecting the transistors from PIDs or monitoring the PIDs may be generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a simplified schematic configuration of an apparatus configured to conduct a plasma etching process, according to one or more aspects of the present disclosure.

FIG. 2 illustrates a flow chart of a method for forming a semiconductor structure with reduced PIDs, according to one or more aspects of the present disclosure.

FIGS. 3, 4, 5, 6, 7, 8, 9, 10, 11, 12, and 14 illustrate fragmentary cross-sectional views of a workpiece during various fabrication stages in the method of FIG. 2, according to one or more aspects of the present disclosure.

FIG. 13 illustrates a simplified equivalent circuit diagram of the workpiece shown in FIG. 12, according to one or more aspects of the present disclosure.

FIG. 15 illustrates a fragmentary layout of the workpiece shown in FIG. 14, according to one or more aspects of the present disclosure.

FIG. 16 illustrates a fragmentary layout of a first alternative semiconductor structure, according to one or more aspects of the present disclosure.

FIG. 17 illustrates a fragmentary cross-sectional view of the first alternative semiconductor structure, according to one or more aspects of the present disclosure.

FIG. 18 illustrates a simplified equivalent circuit diagram of a second alternative semiconductor structure, according to one or more aspects of the present disclosure.

FIG. 19 illustrates a fragmentary cross-sectional view of a third alternative semiconductor structure, according to one or more aspects of the present disclosure.

FIG. 20 illustrates a flow chart of a method for forming another semiconductor structure for PIDs risk assessment, according to one or more aspects of the present disclosure.

FIGS. 21, 22, 23, 24, 25, 26, and 28 illustrate fragmentary cross-sectional views of a workpiece during various fabrication stages in the method of FIG. 20, according to one or more aspects of the present disclosure.

FIG. 27 illustrates a simplified equivalent circuit diagram of the workpiece shown in FIG. 26, according to one or more aspects of the present disclosure.

FIG. 29 illustrates a fragmentary layout of the workpiece shown in FIG. 28, according to one or more aspects of the present disclosure.

FIG. 30 illustrates a fragmentary cross-sectional view of an alternative semiconductor structure, according to one or more aspects of the present disclosure.

FIG. 31 illustrates a simplified equivalent circuit diagram of a semiconductor structure undergoing a plasma etching process, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

IC manufacturing process flow may be typically divided into three categories: front-end-of-line (FEOL) processes, middle-end-of-line (MEOL) processes, and back-end-of-line (BEOL) processes. FEOL processes generally encompasses processes related to fabricating IC devices, such as transistors. For example, FEOL processes may include forming isolation features, gate structures, and source/drain features. Source/drain feature(s) may refer to a source or a drain, individually or collectively dependent upon the context. MEOL processes generally encompasses processes related to fabricating contacts to conductive features of the IC devices, such as gate vias to the gate structures and/or source/drain contacts to the source/drain features. BEOL processes generally encompasses processes related to fabricating multi-layer interconnect structures over or below the transistors to interconnect IC features fabricated by FEOL and MEOL process, thereby enabling operation of the IC devices.

As the dimensions of IC devices shrink, the close proximity among the source/drain contacts and gate vias may reduce process windows for forming these conductive features and may increase parasitic capacitance among them. To alleviate these concerns, some IC chips (e.g., super power rail (SPR) chips) may implement a backside source/drain contact through the substrate to come in contact with a source/drain feature, and a power rail is formed on the back side of the substrate to be in contact with the backside source/drain contact. Since the implementation of SPR structures cases the crowding of contacts, SPR chips entail a modern solution for performance boost on power delivery network (PDN) for advanced technology nodes.

However, as described above, formation of these metal lines and contact via of the multi-layer interconnect structures may include use of dry etch processes that are aided by plasma. As more and more metal lines and contact vias are formed, they may inevitably serve as an antenna to collect charges generated by incident of plasma. When sufficient charge is accumulated at an electrically isolated node, the charge may cause high-field stress on dielectric features, such as a gate dielectric layer. The stress may cause damages to the transistors. For example, when this happens to a gate dielectric layer, the high-field stress may cause breakdown of the gate dielectric layer and total failure of the transistor. This type of damages may be generally referred to as plasma process-induced damages (PIDs). Processes of forming the SPR chips do not intrinsically provide an electrical connection from the power rail to a carrier substrate to discharge the charges generated by incident of plasma. It is desirable to prevent or alleviate PIDs for SPR chips.

The present disclosure provides methods of protecting semiconductor structures from PIDs. In an embodiment, a first antenna is electrically coupled to a source terminal of a transistor, and a second antenna is electrically coupled to a gate terminal of the transistor. During the performing of a plasma etching process, the first antenna will be exposed to the plasma earlier than the second antenna and serve as a lightning rod to provide a discharge path for some charged ions in the plasma. As such, gate-source cross voltage Vgs between the gate terminal and the source terminal of the transistor will be decreased, thereby reducing the susceptibility or degree of PIDs to the transistor. The chronological order of turning on the first antenna and second antenna is achieved by forming trenches with different aspect ratios. More specifically, the aspect ratio dependent etching (ARDE) effect causes bigger features to be etched at faster rates. The present disclosure also provides methods of monitoring PIDs. In this embodiment, the second antenna will be exposed to the plasma earlier than the first antenna by forming larger vias over the second antenna, such that the reliability of the transistor may be rigorously evaluated. Compared with some existing technologies, the semiconductor structures and methods of the present disclosure implement design-rule compliant layouts without introducing additional protection devices while allowing the proper monitoring of layout-dependent effects.

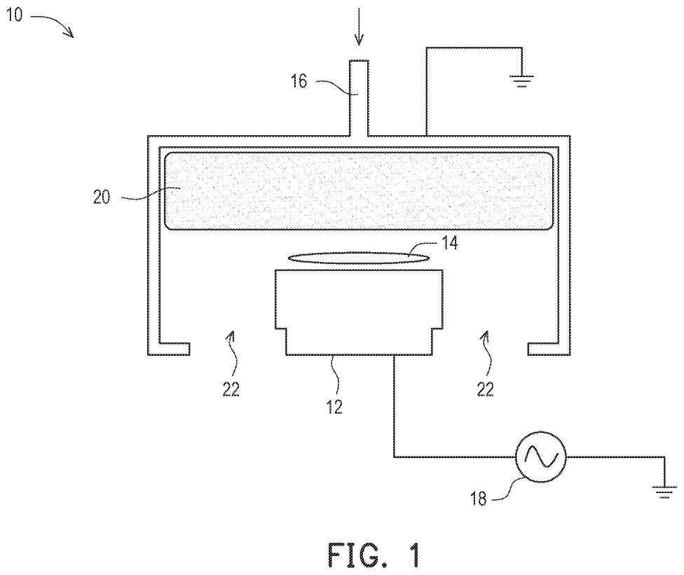

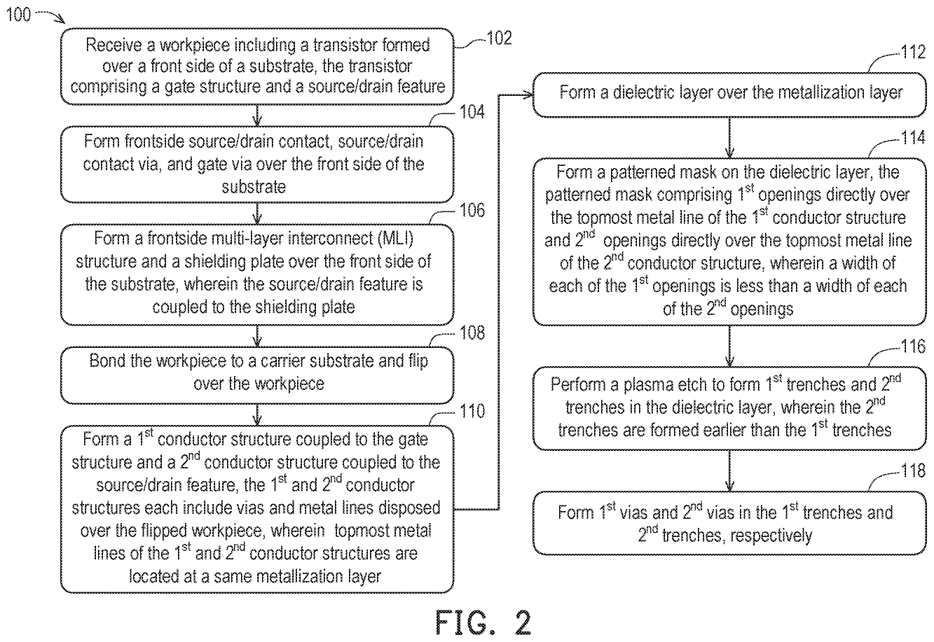

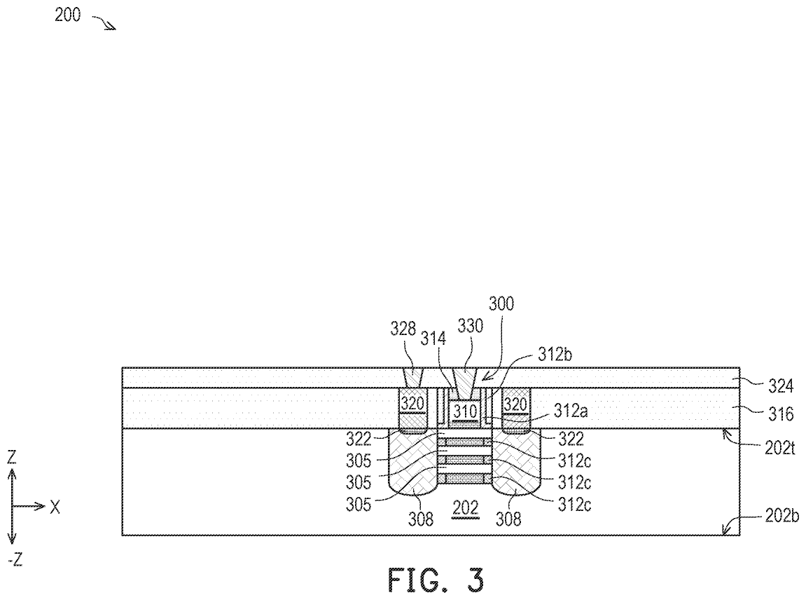

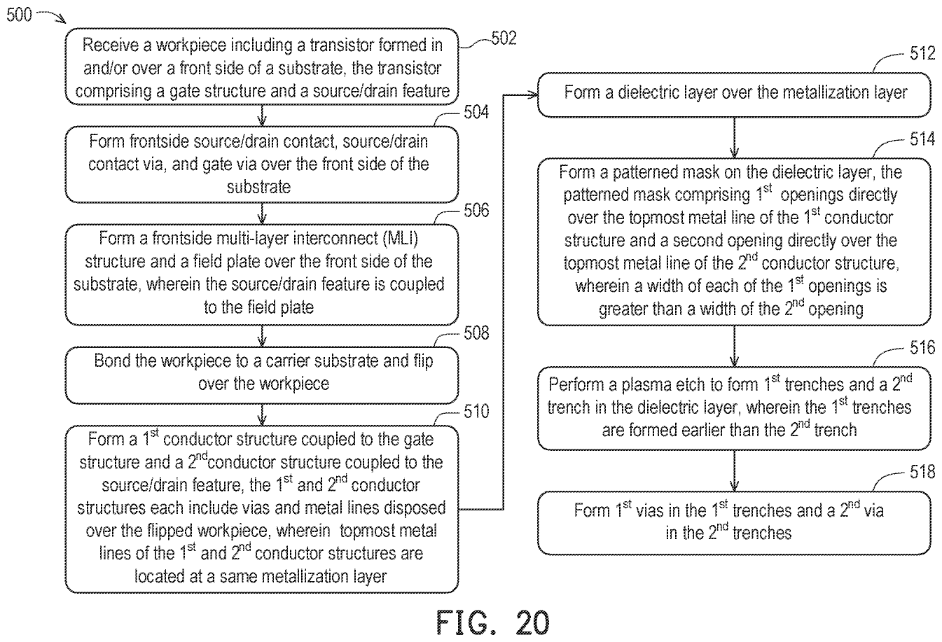

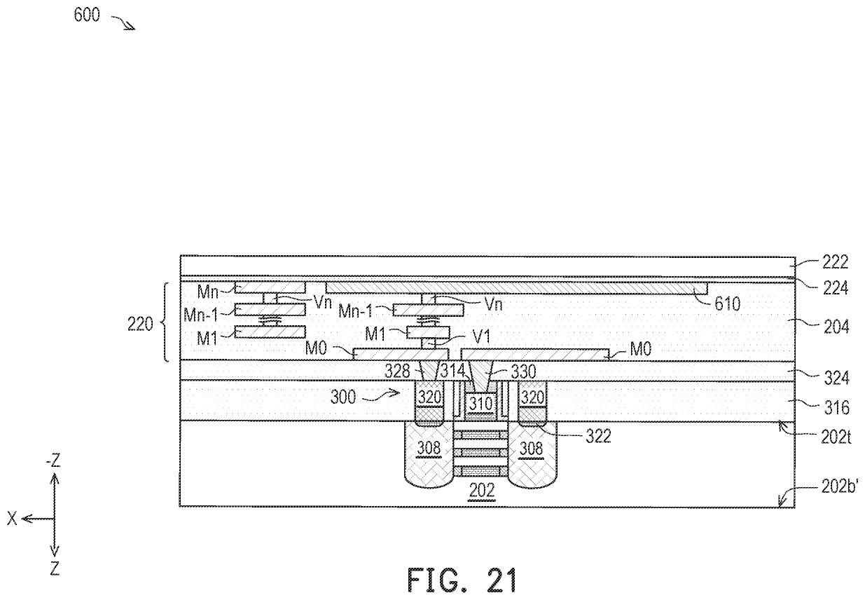

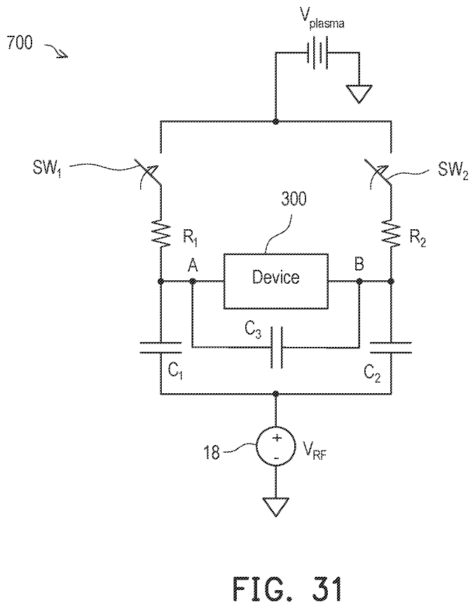

The various aspects of the present disclosure will now be described in more detail with reference to the figures. In that regard, FIG. 1 shows a simplified schematic configuration of an apparatus configured to conduct a plasma etching process. FIG. 2 is a flow chart illustrating a method 100 for forming a semiconductor structure 200 with reduced PIDs, according to one or more aspects of the present disclosure. Method 100 is described below in conjunction with FIGS. 3-19, which are fragmentary cross-sectional views, fragmentary layout views, or simplified equivalent circuit diagrams of a workpiece 200 at different stages of fabrication according to embodiments of method 100. FIG. 20 is a flow chart illustrating a method 500 of forming a semiconductor structure 600 for monitoring PIDs, according to one or more aspects of the present disclosure. Method 500 is described below in conjunction with FIGS. 21-30, which are fragmentary cross-sectional views, fragmentary layout views, or simplified equivalent circuit diagrams of a workpiece 600 at different stages of fabrication according to embodiments of method 500. FIG. 31 illustrates a simplified equivalent circuit diagram of a semiconductor structure undergoing a plasma etching process, according to one or more aspects of the present disclosure. Method 100 and method 500 are merely examples and are not intended to limit the present disclosure to what are explicitly illustrated therein. Additional steps may be provided before, during, and/or after the method, and some steps described can be replaced, eliminated, or moved around for additional embodiments of the method. Not all steps are described herein in detail for reasons of simplicity. Because the workpiece 200/600 will be fabricated into a semiconductor structure 200/600 upon conclusion of the fabrication processes, the workpiece 200/600 may be referred to as the semiconductor structure 200/600 as the context requires. For avoidance of doubts, the X, Y and Z directions in the figures are perpendicular to one another and are used consistently. Throughout the present disclosure, like reference numerals denote like features unless otherwise excepted.

Referring to FIG. 1, a simplified schematic configuration of an apparatus 10 for conducting a plasma etching process is illustrated in accordance with an embodiment. As shown in FIG. 1, a wafer 14 is placed on a chuck 12 of the apparatus 10. In accordance with an embodiment, the apparatus 10 may employ a plasma etching mechanism. As required by plasma etching mechanism, a variety of gases are supplied from an inlet 16. Through an ionization process, plasma 20 including a plurality of ions is generated in the apparatus 10. The apparatus 10 includes two electrodes. As shown in FIG. 1, the wall of the apparatus 10 is used as a first electrode, which is connected to ground. The chuck 12 of the apparatus 10 is used as a second electrode, which is powered by a radio frequency (RF) power source 18. The first electrode and the second electrode form an electrical field, through which the ions of the plasma 20 are accelerated. During a plasma etching process, the accelerated ions hit the surface of the wafer 14. As a result, the atoms on the unprotected surface of the wafer 14 are dislodged so that a portion of the wafer 14 is removed. The electrical potential of the wafer 14 may be influenced by both the RF power source 18 from the bottom and the potential associated with the plasma 20 on its top. That is, voltage stress may develop across a victim device (e.g., the transistor 300 shown in FIG. 3) of the wafer 14 during the performing of the plasma etching process. The apparatus 10 may further include one or more outlets such as outlet 22. In an etching process, a large amount of byproduct gas may be generated. Such byproducts may be removed continuously by vacuum pumps (not shown) through the outlet 22. In some embodiments, the apparatus 10 may be a process chamber of a semiconductor apparatus.

Referring to FIGS. 2 and 3, method 100 includes a block 102 where a workpiece 200 is received. The workpiece 200 includes a substrate 202 having a top surface 202t and a bottom surface 202b opposite the top surface 202t. In an embodiment, the substrate 202 is a bulk silicon substrate (i.e., including bulk single-crystalline silicon). The substrate 202 may include other semiconductor materials in various embodiments, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof, or other suitable materials. In some alternative embodiments, the substrate 202 may be a semiconductor-on-insulator substrate, such as a silicon-on-insulator (SOI) substrate, a silicon germanium-on-insulator (SGOI) substrate, or a germanium-on-insulator (GOI) substrate. The substrate 202 may include multiple doped regions (e.g., N-type doped wells, P-type doped wells). Each of the N-type doped wells may be doped with an N-type dopant, such as phosphorus, arsenic, other N-type dopants, or combinations thereof. Each P-type doped wells may be doped with a P-type dopant, such as boron, indium, other P-type dopants, or combinations thereof. Each of the various doped regions may be formed by performing an ion implantation process, a diffusion process, other suitable doping processes, or combinations thereof.

The workpiece 200 also includes a transistor 300 formed in and/or over the top surface 202t of the substrate 202. In the present embodiments, the transistor 300 is a gate-all-around (GAA) transistor. The transistor 300 includes a number of channel layers 305 stacked vertically along the Z direction. Each of the channel layers 305 may include Si, Ge, SiC, SiGe, GeSn, SiGeSn, SiGeCSn, other suitable semiconductor materials, or combinations thereof. In the present embodiments, each of the channel layers 305 includes Si in the form of a nanosheet, a nanowire (e.g., a nanowire having a hexagonal cross-section), a nanorod (e.g., a nanorod having a square or round cross-section), or other suitable configurations. In some embodiments, the transistor 300 includes two to ten channel layers 305. Of course, the present disclosure is not limited to such configurations and the number of channel layers 305 may be tuned according to design requirements for the semiconductor structure 200.

The transistor 300 also includes source/drain features 308 coupled to the channel layers 305. The transistor 300 may be an N-type transistor or a P-type transistor, and the source/drain features 308 may be N-type source/drain features or P-type source/drain features, accordingly. Exemplary N-type source/drain features may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process. Exemplary P-type source/drain features may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. In some embodiments, each of the source/drain features 308 may be a multi-layer structure that includes an undoped semiconductor layer, a lightly doped semiconductor layer, and a heavily doped semiconductor layer. In an embodiment, the transistor 300 is an N-type transistor.

The transistor 300 also includes a gate structure 310 wrapping around and over each of the channel layers 305. The gate structure 310 includes at least a high-K gate dielectric layer (not separately labeled) and a metal gate electrode (not separately labeled) over the high-K gate dielectric layer. The high-K gate dielectric layer may include silicon oxynitride, aluminum silicon oxide, a high-K dielectric material such as hafnium oxide, zirconium oxide, lanthanum oxide, titanium oxide, yttrium oxide, strontium titanate, other suitable dielectric materials, or combinations thereof. Though not depicted, each metal gate electrode may include a bulk conductive layer. The bulk conductive layer may include Cu, W, Ru, Co, Al, Ti, Ta, other suitable metals, or combinations thereof. In some examples, each gate structure may include one or more work function metal layer of the same conductivity type or of different conductivity types. Examples of the work function metal layers may include TIN, TaN, Ru, Mo, Al, WN, ZrSi₂, MoSi₂, TaSi₂, NiSi₂, Ti, Ag, TaAl, TaAlC, TiAlN, TaC, TaCN, TaSiN, Mn, Zr, other suitable work function materials, or combinations thereof. Additional material layers may also be included in each gate structure, such as an interfacial layer, a barrier layer, a capping layer, other suitable materials layers, or combinations thereof. PIDs to the transistor 300 (i.e., victim device) may be either reduced or monitored, according to different embodiments of the present disclosure.

The transistor 300 also includes top spacers 312a and 312b and inner spacers 312c disposed on sidewalls of the gate structure 310, where the top spacers 312a and 312b are disposed over the topmost channel layer 305 and the inner spacers 312c are disposed in the space between two vertically stacked channel layers 305. In some embodiments, the top spacers 312a and 312b may include silicon oxide, silicon oxycarbide, silicon carbonitride, silicon nitride, zirconium oxide, aluminum oxide, or other suitable dielectric materials. The inner spacers 312c may include silicon oxide, silicon nitride, silicon oxycarbide, silicon oxycarbonitride, silicon carbonitride, metal nitride, or a suitable dielectric material. In some embodiments, the transistor 300 also includes a dielectric capping layer 314 formed on the gate structure 310. The top spacers 312a and 312b also extend along the sidewall surface of the dielectric capping layer 314. In some other embodiments, the dielectric capping layer 314 may be formed on and in direct contact with both the gate structure 310 and the top spacers 312a and 312b.

The transistor 300 also includes a dielectric structure 316 over the source/drain features 308 and adjacent to the sidewalls of the top spacers 312a and 312b. In some embodiments, the dielectric structure 316 includes a contact etch stop layer (CESL) and an interlayer dielectric (ILD) layer disposed over the contact etch stop layer (CESL). The CESL may include silicon nitride, silicon oxynitride, and/or other materials known in the art and may be formed by atomic layer deposition (ALD) process, plasma-enhanced chemical vapor deposition (PECVD) process and/or other suitable deposition or oxidation processes. The ILD layer may be deposited by a PECVD process or other suitable deposition technique over the source/drain features 308 after the deposition of the CESL. The ILD layer may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

Still referring to FIGS. 2 and 3, method 100 includes a block 104 where source/drain contacts 320, a source/drain contact via 328, and a gate via 330 are formed over the top surface 202t (or front side) of the substrate 202. In an exemplary process, a patterned mask layer (not shown) is formed over the transistor 300, and while using the patterned mask layer as an etch mask, an etching process may be performed to remove portions of the dielectric structure 316 to form source/drain contact openings exposing the source/drain features 308. Silicide layers 322 and source/drain contacts 320 are then formed in the source/drain contact openings. The source/drain contact 320 is electrically couple to the source/drain feature 308 via the silicide layer 322. Since the source/drain contacts 320 are formed over the front side of the substrate 202, the source/drain contacts 320 may be referred to as frontside source/drain contacts 320. The frontside source/drain contacts 320 may include any suitable conductive material, such as Cu, W, Ru, Co, Al, Ti, Ta, other suitable metals, or combinations thereof. Each source/drain contacts 320 may further include a barrier layer comprising any suitable material, such as Ti, Ta, TiN, TaN, other suitable materials, or combinations thereof. The silicide layer 322 may include nickel silicide, titanium silicide, cobalt silicide, other suitable silicides, or combinations thereof. After forming the frontside source/drain contacts 320, a dielectric layer 324 is formed over the transistor 300. In an embodiment, the dielectric layer 324 is a dual-layer structure including a dielectric material layer (e.g., ILD layer) formed on an etch stop layer and may be formed in a way similar to the dielectric structure 316. A source/drain contact via 328 is formed over and in direct contact with the frontside source/drain contact 320, and a gate via 330 is formed over and in direct contact with the gate structure 310 of the transistor 300. The compositions and formations of the source/drain contact via 328 and gate via 330 may be similar to those of the frontside source/drain contacts 320 and repeated description is omitted for reason of simplicity.

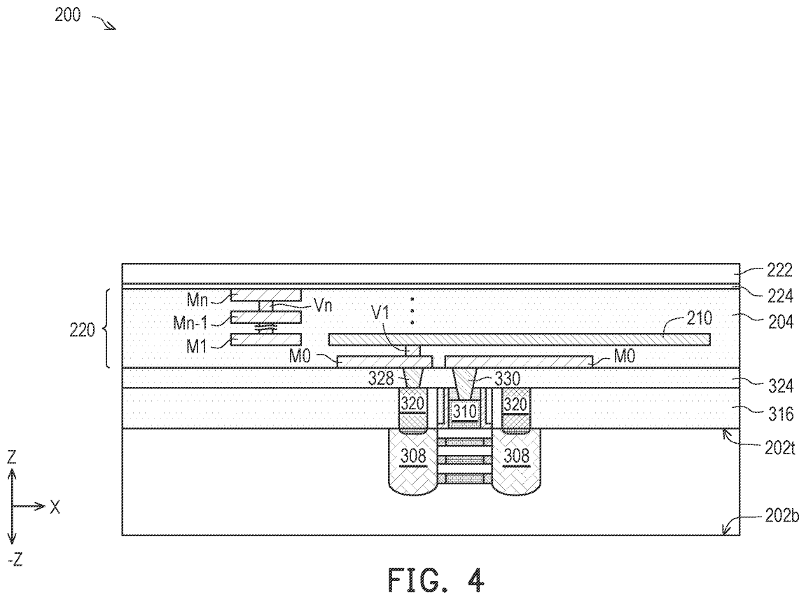

Referring to FIGS. 2 and 4, method 100 includes a block 106 where a frontside multi-layer interconnect (FMLI) structure 220 is formed over the front side of the substrate 202. The frontside multi-layer interconnect (FMLI) structure 220 may include a number of interconnect layers (or “metallization layers”) that include interconnection elements such as metal lines, as well as conductive vias that vertically interconnect different metal lines from different interconnect layers. The interconnect layers that include metal lines extending through dielectric layers may be referred to as metal line layers (e.g., metal line layers M0, M1, . . . . Mn−1, Mn), and the interconnect layers that include conductive vias extending through dielectric layers may be referred to as metal via layers (e.g., metal via layers V1, . . . . Vn). The dielectric layers of the FMLI structure 220 are collectively referred to as a dielectric structure 204. The metal line layers M0, M1, . . . . Mn−1, Mn, are formed over one another and include horizontally extending metal lines, where n is a positive integer and denotes the layer index. The metal via layers are formed over one another, and a metal via layer (e.g., Vn) is interposed between an underlying metal line layer (e.g., Mn−1) and an overlying metal line layer (e.g., Mn) and electrically connects the two vertically adjacent metal line layers. Metal lines formed at the metal line layers M0, M1, . . . . Mn may be referred to as M0 metal lines, M1 metal lines, . . . . Mn metal lines, respectively, and conductive vias V1, . . . . Vn formed at the metal via layers V1, . . . . Vn may be referred to as V1 vias, . . . . Vn vias, respectively. The metal lines and vias may be formed by various methods such as a dual damascene mechanism, a single damascene mechanism, or other suitable methods. In some embodiments, each of the metal lines and vias of the FMLI structure 220 may include a barrier layer and a metal fill layer disposed on the barrier layer. The barrier layer may include Ti, Ta, TiN, or TaN. The metal fill layer may include cobalt, ruthenium, tungsten, aluminum, or combinations thereof.

In the present embodiments, a shielding plate 210 is formed along with the metal lines of the FMLI structure 220. The shielding plate 210 is configured to reduce or even block electromagnetic field related to a RF power source (e.g., the RF power source 18 shown in FIG. 1) during the performing of a plasma etching process such that one node (i.e., the source/drain feature 308) of the transistor 300 is coupled more to the plasma 20 than being coupled to the RF power source 18. To effectively reduce the electromagnetic field related to the RF power source 18, the shielding plate 210 is located at one of the lower levels of the metal line layers of the FMLI structure 220. For example, in the illustrated embodiments, the shielding plate 210 is located at the metal line layer M1 and is electrically coupled to the source/drain feature 308 by way of the M0 metal line, the source/drain contact via 328, the source/drain contact 320 and the silicide layer 322.

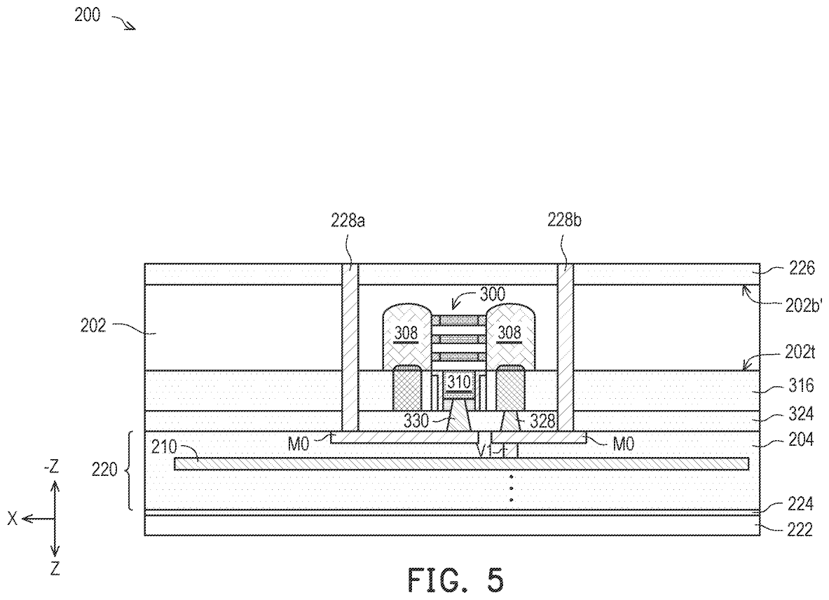

Referring to FIGS. 2 and 4-5, method 100 includes a block 108 where the workpiece 200 is bonded to a carrier substrate 222. In some embodiments, the carrier substrate 222 may be bonded to the workpiece 200 by fusion bonding, by use of an adhesion layer, or a combination thereof. In some instances, the carrier substrate 222 may include semiconductor materials (such as silicon), sapphire, glass, polymeric materials, or other suitable materials. In the present embodiments, the carrier substrate 222 is bonded to the FMLI structure 220 by use of an adhesion layer 224. Once the carrier substrate 222 is bonded to the FMLI structure 220 of the workpiece 200, as represented by FIG. 5, the workpiece 200 is flipped over and planarized from the bottom surface 202b of the substrate 202 to reduce a thickness of the substrate 202 to facilitate the formation of features under the transistor 300. The bottom surface 202b of the substrate 202 after the performing of the planarization is referred to as the bottom surface 202b′. All processes that are implemented to form features under the back side of the transistor 300 are performed when the workpiece 200 is flipped over.

Referring to FIGS. 2 and 5-6, method 100 includes a block 110 where a first conductor structure 242a is formed to couple to the gate structure 310 and a second conductor structure 242b is formed to couple to one of the source/drain features 308. With reference to FIG. 5, after flipping the workpiece 200 and reducing the thickness of the substrate 202, a dielectric layer 226 is formed on the planarized bottom surface 202b′ of the substrate 202. The dielectric layer 226 may be formed using a deposition process, such as chemical vapor deposition (CVD), physical vapor deposition (PVD), atomic layer deposition (ALD), or other suitable materials. In some embodiments, the dielectric layer 226 may include a dielectric material, such as silicon oxide or silicon nitride. It is noted that some features of the FMLI structure 220 are omitted in FIG. 5 and some of the subsequent figures for brevity.

In the present embodiments, after forming the dielectric layer 226, as shown in FIG. 5, a first via 228a and a second via 228b are formed to electrically couple to the gate structure 310 and the source/drain feature 308, respectively. More specifically, the first via 228a extends through the dielectric layer 226, the substrate 202, and the dielectric structure 316 and the dielectric layer 324 to direct contact the M0 metal line that is in direct contact with the gate via 330; the second via 228b extends through the dielectric layer 226, the substrate 202, and the dielectric structure 316 and the dielectric layer 324 to direct contact the M0 metal line that is in direct contact with the source/drain contact via 328. Although not shown, in some embodiments, a dielectric liner is formed to extend along sidewalls of the first via 228a and the second via 228b such that the first and second vias 228a-228b are electrically isolated from the substrate 202.

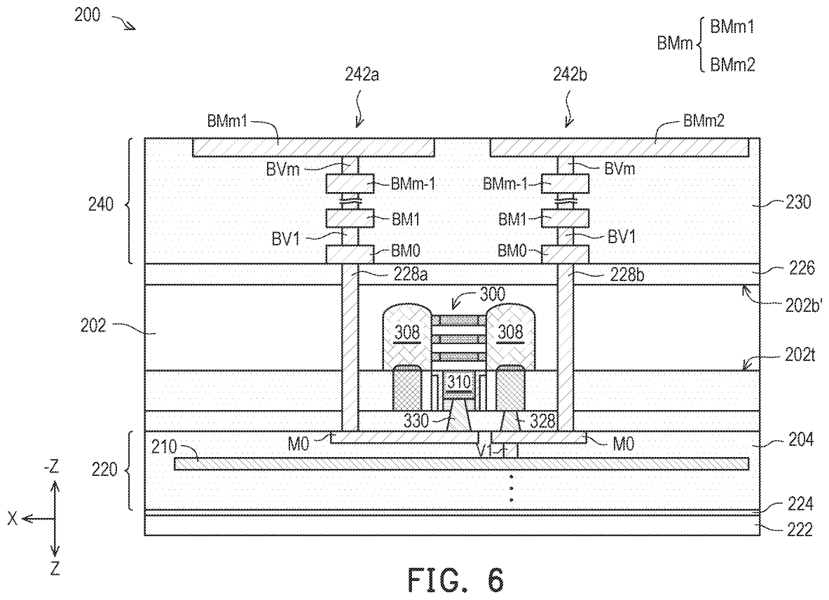

With reference to FIG. 6, a backside multi-layer interconnect (BMLI) structure 240 is formed over the bottom surface 202b′ of the substrate 202. The backside multi-layer interconnect (BMLI) structure 240 may include a number of interconnect layers (or “metallization layers”) that include interconnection elements such as metal lines, as well as conductive vias that vertically interconnect different metal lines from different interconnect layers. The interconnect layers that include metal lines extending through dielectric layers may be referred to as metal line layers (e.g., metal line layers BM0, BM1, . . . . BMm−1, BMm), and the interconnect layers that include conductive vias extending through dielectric layers may be referred to as metal via layers (e.g., metal via layers BV1, . . . . BVn). The dielectric layers of the BMLI structure 240 are collectively referred to as a dielectric structure 230. The metal line layers BM0, BM1, . . . . BMm−1, BMm are formed over one another and include horizontally extending metal lines, where m is an integer and denotes the layer index. The metal via layers are formed over one another, and a metal via layer (e.g., BVn) is interposed between and electrically connects an underlying metal line layer and an overlying metal line layer. Metal lines formed at the metal line layers BM0, BM1, . . . . BMm may be referred to as BM0 metal lines, BM1 metal lines, . . . . BMm metal lines, respectively, and conductive vias BV1, . . . . BVm formed at the metal via layers BV1, . . . . BVm may be referred to as BV1 vias, . . . . BVm vias, respectively. Since the backside multi-layer interconnect (BMLI) structure 240 are formed over the back side of the transistor 300, the metal lines and vias of the backside multi-layer interconnect (BMLI) structure 240 may be referred backside metal lines and backside vias, respectively. For ease of description, the BMm metal line that is electrically coupled to the gate structure 310 of the transistor 300 is referred to as the metal line BMm1, and the BMm metal line that is electrically coupled to the source/drain feature 308 of the transistor 300 is referred to as the metal line BMm2. The metal line BMm1 and metal line BMm2 are located at a same metal line layer and will be exposed to plasma 20 in subsequent processes, this metal line layer may also be referred to as a target layer.

The metal line BMm1 and conductive features (i.e., BM0 metal line, BV1 via, BM1 metal line, . . . . BVm via) that couple the metal line BMm1 to the first via 228a are collectively referred to as a first conductor structure 242a; the metal line BMm2 and conductive features (i.e., BM0 metal line, BV1 via, BM1 metal line, . . . . BVm via) that couple the metal line BMm2 to the second via 228b are collectively referred to as a second conductor structure 242b. Each of the first conductor structure 242a and the second conductor structure 242b may function as an antenna during subsequent fabrication processes (e.g., the plasma etching process 250).

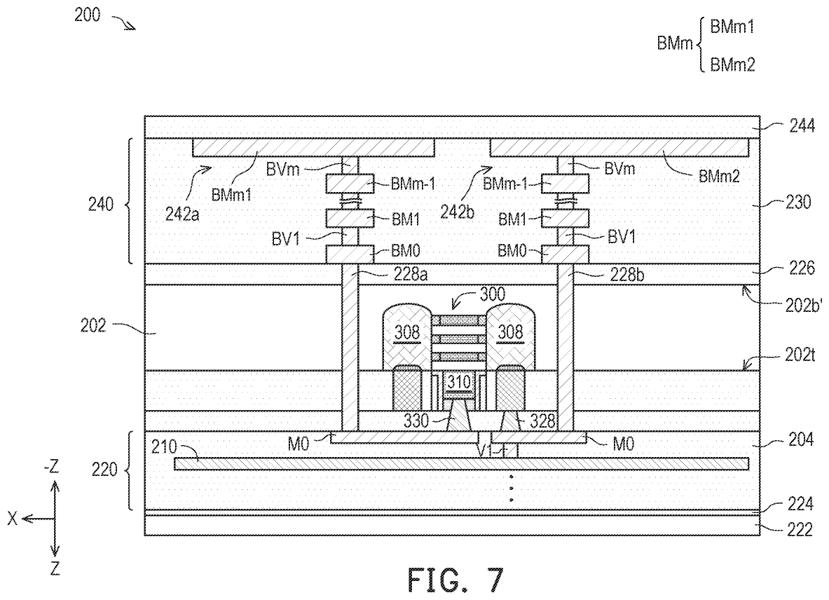

Referring to FIGS. 2 and 7, method 100 includes a block 112 where a dielectric layer 244 is formed over the metal line layer BMm. The dielectric layer 244 may be formed using a deposition process, such as chemical vapor deposition (CVD), physical vapor deposition (PVD), atomic layer deposition (ALD), or other suitable materials. In some embodiments, the dielectric layer 244 may include a dielectric material, such as silicon oxide or silicon nitride. In other embodiments, the dielectric layer 244 may include a polymer material. In some embodiments, the dielectric layer 244 is a dual-layer structure that includes an interlayer dielectric (ILD) layer formed over an etch stop layer.

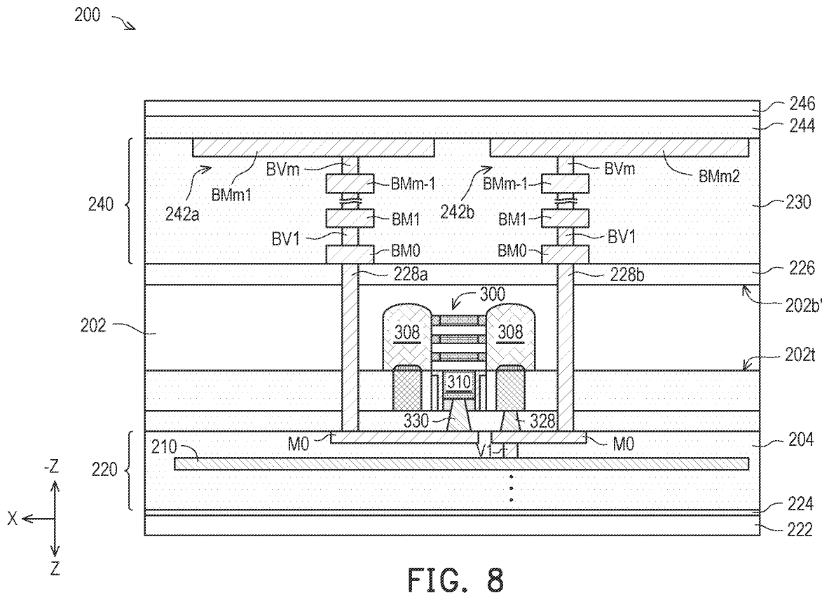

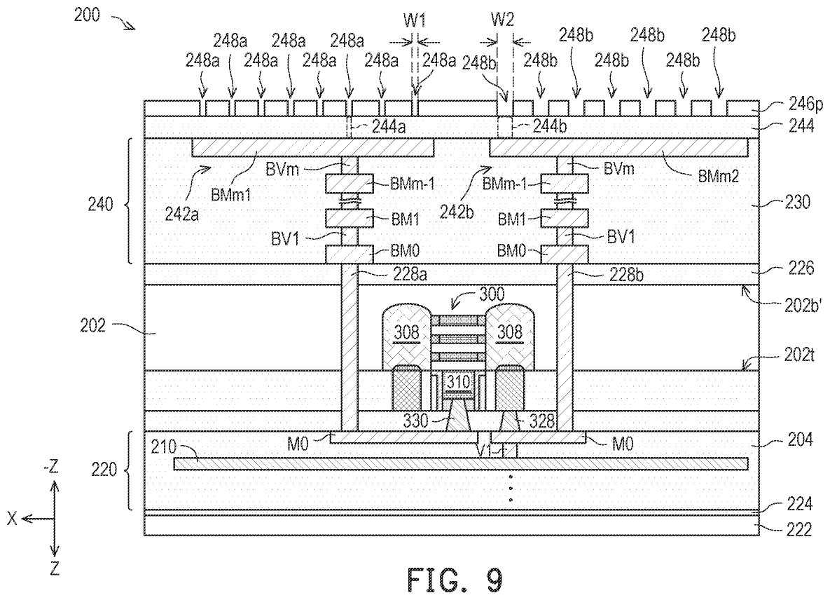

Referring to FIGS. 2 and 8-9, method 100 includes a block 114 where a patterned mask 246p is formed on the dielectric layer 244. In an example process, with reference to FIG. 8, a mask film 246 is formed on the dielectric layer 244. The mask film 246 may include a hard mask layer, a photoresist layer, or a combination thereof. For example, the mask film 246 is deposited over the workpiece 200 using CVD, subatmospheric CVD (SACVD), flowable CVD (FCVD), physical vapor deposition (PVD), spin-on coating, and/or other suitable process. After forming the mask film 246, with reference to FIG. 9, the mask film 246 is patterned using a combination of lithography and etch steps to form first openings 248a and second openings 248b exposing portions of the dielectric layer 244. An exemplary lithography process includes soft baking of the photoresist layer of the mask film 246, mask aligning, exposing, post-exposure baking, developing the photoresist layer of the mask film 246, rinsing, and drying (e.g., hard baking). In the present embodiment, each of the first openings 248a exposes a first portion (e.g., 244a) of the dielectric layer 244 thereunder, and each of the second openings 248b exposes a second portion (e.g., 244b) of the dielectric layer 244, and when viewed from top, the area of the second portion 244b of the dielectric layer 244 is greater than the area of the first portion 244a of the dielectric layer 244. In an embodiment, the first opening 248a spans a width W1 along the X direction, the second opening 248b spans a width W2 along the X direction, and the width W2 is greater than the width W1. In some embodiments, the density (i.e., the quantity per unit volume) of the first openings 248a is greater than the density of the second openings 248. The mask film 246 after the patterning may be referred to as the patterned mask 246p.

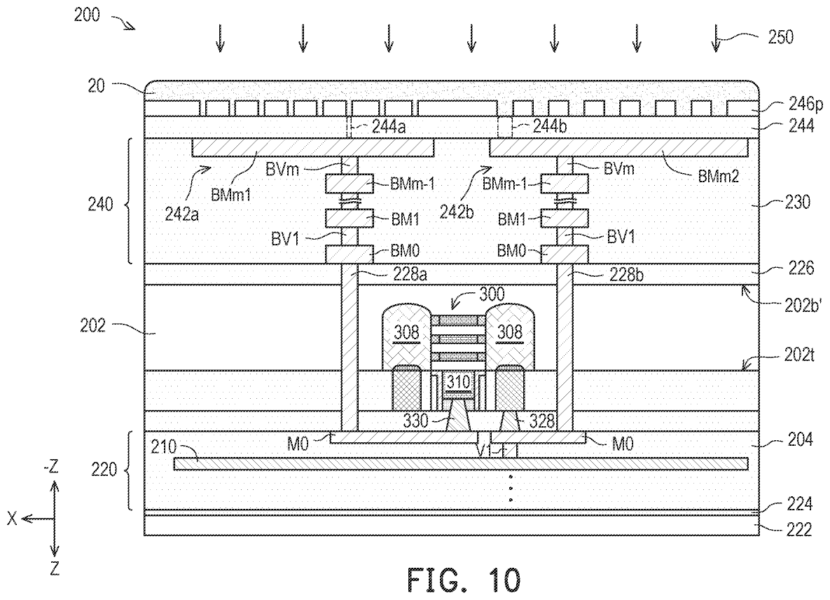

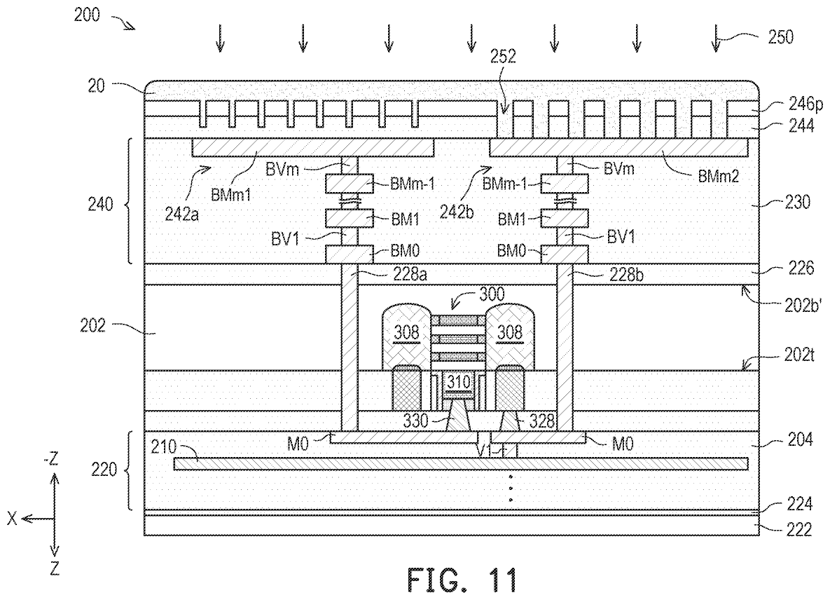

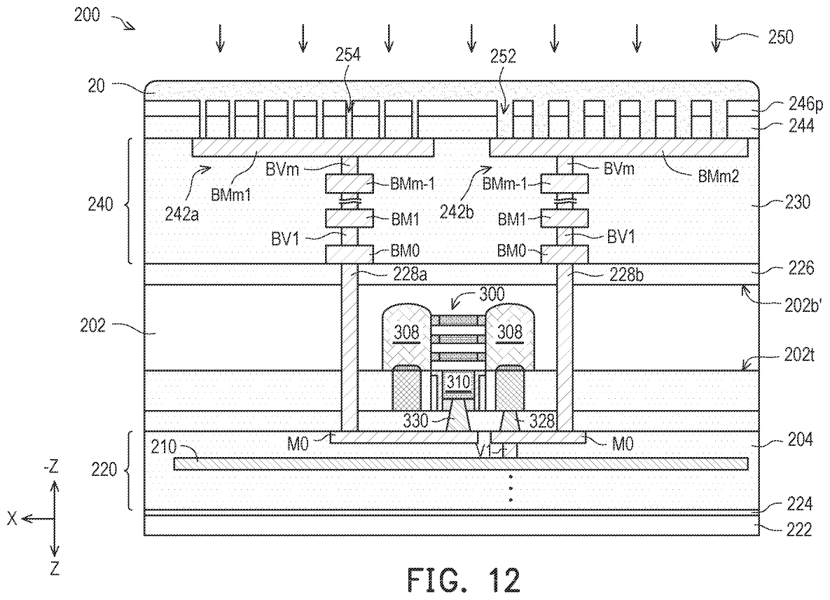

Referring to FIGS. 1, 2, 10, 11, 12, and 13, method 100 includes a block 116 where a plasma etching process 250 is performed to form first trenches 252 and second trenches 254 in the dielectric layer 244. After forming the patterned mask 246p, the workpiece 200 is placed in the chamber of the apparatus 10 to undergo the plasma etching process 250. As illustrated by FIG. 10, top and sidewall surfaces of the patterned mask 246p and top surfaces of the first and second portions (e.g., 244a, 244b) of the dielectric layer 244 are exposed in the plasma environment. After performing the plasma etching process 250 for a first duration TI of time, as represented by FIG. 11, the second portion 244b of the dielectric layer 244 exposed by the second openings 248b is substantially removed to form first trenches 252 (filled by plasma 20) exposing portions of the metal line BMm2 thereunder, while the first portion 244a of the dielectric layer 244 exposed by the first openings 248a is only partially removed. That is, after the first duration TI of time, the metal line BMm1 has not been exposed to the plasma 20. Put differently, the plasma etching process 250 etches the first portion 244a at a first etch rate and etches the second portion 244b at a second etch rate that is higher than the first etch rate. The different etch rates are related to the configurations (e.g., widths) of the first openings 248a and the second openings 248b. More specifically, for features with different dimensions etched simultaneously, aspect ratio dependent etching (ARDE) effect causes bigger features to be etched at faster rates. With the continuously performing of plasma etching process 250, as represented by FIG. 12, the first portion 244a of the dielectric layer 244 exposed by the first openings 248a will be fully removed, thereby forming second trenches 254 exposing portions of the metal line BMm1 thereunder. That is, the first trenches 252 are formed earlier than the second trenches 254. Each of the second trenches 254 has a width (e.g., W1) smaller than the width (e.g., W2) of the trench 252. The performing of the plasma etching process 250 may be stopped upon formation of the second trenches 254, and the patterned mask 246p may be then selectively removed.

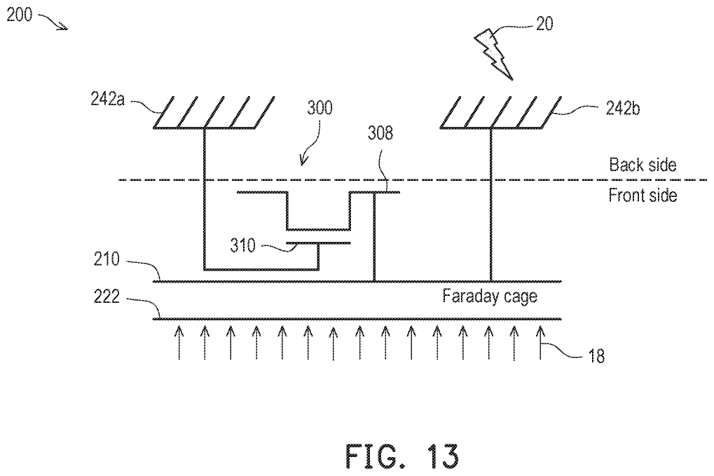

Forming the first trenches 252 and the second trenches 254 in a chronological order reduces the susceptibility or degree of damage to the transistor 300. As described above, the shielding plate 210 blocks the electromagnetic field related to the RF power source 18. That is, before the performing of the plasma etching process 250, the shielding plate 210 is set to float. During the performing of the plasma etching process 250, each of the first conductor structure 242a and the second conductor structure 242b may function as an antenna, and the two antennas are turned on in a chronological order. Specifically, with reference to FIGS. 11 and 12, during the performing of the plasma etching process 250, the metal line BMm2 would be exposed to the plasma 20 earlier than the metal line BMm1. That is, a portion of the charge from the charged ions in the plasma 20 will be collected by the second conductor structure 242b (or the “second antenna 242b”) first. The charge captured through the second antenna 242b would flow into the shielding plate 210 and define an electrical potential for the shielding plate 210 and thus define an electrical potential Vs for the source/drain terminal (or source/drain feature 308) of the transistor 300. The metal line BMm1 would be exposed to the plasma 20 after the shielding plate 210 is “turned on” (e.g., having a defined electrical potential). Another portion of the charge from the charged ions in the plasma 20 will be collected by the first conductor structure 242a (or the “first antenna 242a”) and accumulate at the gate structure 310 of the transistor 300. However, since a portion of the charge in the plasma 20 is accumulated at the source/drain feature 308 of the transistor 300, and the shielding plate 210 blocks the electromagnetic field related to the RF power source 18, the charge from the charged ions in the plasma 20 collected by the first conductor structure 242a and accumulated by the gate structure 310 is reduced. As a result, gate-source cross voltage Vgs between gate terminal and source/drain terminal of the transistor 300 (i.e., the voltage difference between the voltage at the gate structure 310 and the voltage at the source/drain feature 308) is advantageously reduced, leading to a lower susceptibility or reduced degree of damage to the transistor 300. FIG. 13 depicts a simplified schematic diagram of the workpiece 200 shown in FIG. 12. As described above, the second antenna 242b that is electrically coupled to the source/drain terminal of the transistor 300 is turned on earlier than the first antenna 242a that is electrically coupled to the gate terminal of the transistor 300. In other words, the second antenna 242b may serve as a lightning rod to provide a discharge path for a portion of the charge from the charged ions in the plasma 20.

Referring to FIGS. 2 and 14-15, method 100 includes a block 118 where vias 256a and vias 256b are formed in the second trenches 254 and first trenches 252, respectively. The vias 256a and vias 256b track the shapes of the second trenches 254 and first trenches 252, respectively. That is, each of the vias 256a has the width W1, and each of the vias 256b has the width W2 that is greater than the width W1. The vias 256a and 256b may be formed by depositing a conductive material layer over the workpiece 200 and planarizing the workpiece 200 to remove excess portions the conductive material layer outside the second trenches 254 and first trenches 252. The conductive material layer may be a single-layer structure or a dual-layer structure that includes a metal fill layer disposed on a barrier liner. The barrier liner may include Ti, Ta, TiN, or TaN. The metal fill layer may include cobalt, ruthenium, tungsten, aluminum, or combinations thereof. Further processes may be performed to form additional metal lines and/or vias over the vias 256a and 256b.

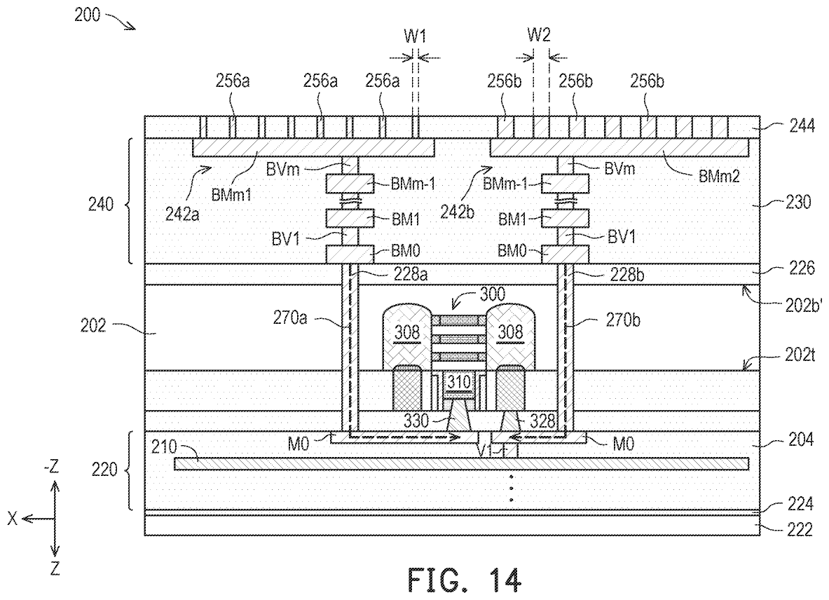

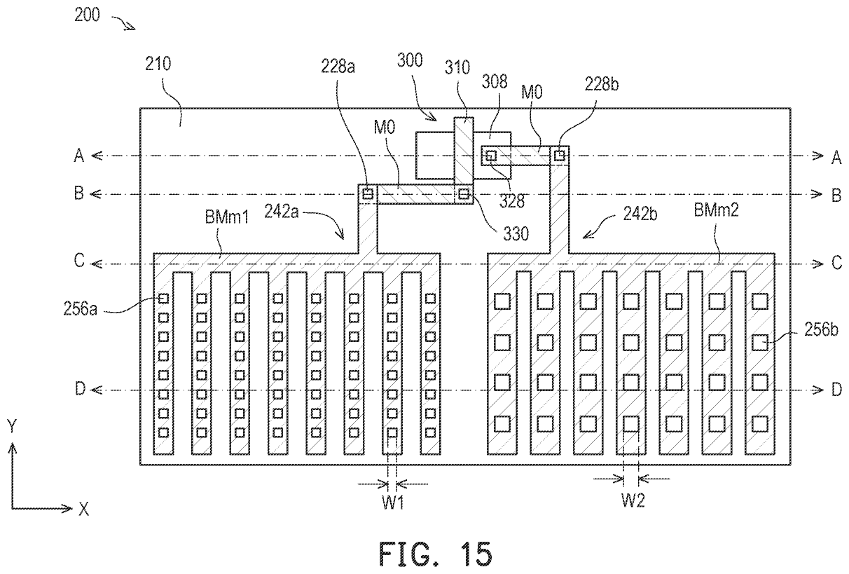

FIG. 15 depicts a fragmentary layout of the workpiece 200 shown in FIG. 14. Some features are omitted in FIG. 15 for reason of simplicity. The fragmentary cross-sectional view shown in FIGS. 3-12 and 14 may be a fragmentary composite cross-sectional view of the workpiece 200 that is a combination of the fragmentary cross-sectional views taken along line A-A, line B-B, line C-C, and line D-D. In the present embodiments, the shielding plate 210 is vertically overlapped with the metal line BMm1, the metal line BMm2 and the transistor 300. In the present embodiments, when viewed from top, each of the metal line BMm1 and the metal line BMm2 has a single-sided comb-like structure. It is understood that the metal line BMm1 and the metal line BMm2 may have other suitable profiles (e.g., double-sided comb-like structure, a rectangular shape). The first and second antenna structures 242a-242b and/or the vias 256a-256b may be placed in scribe lines or in dies.

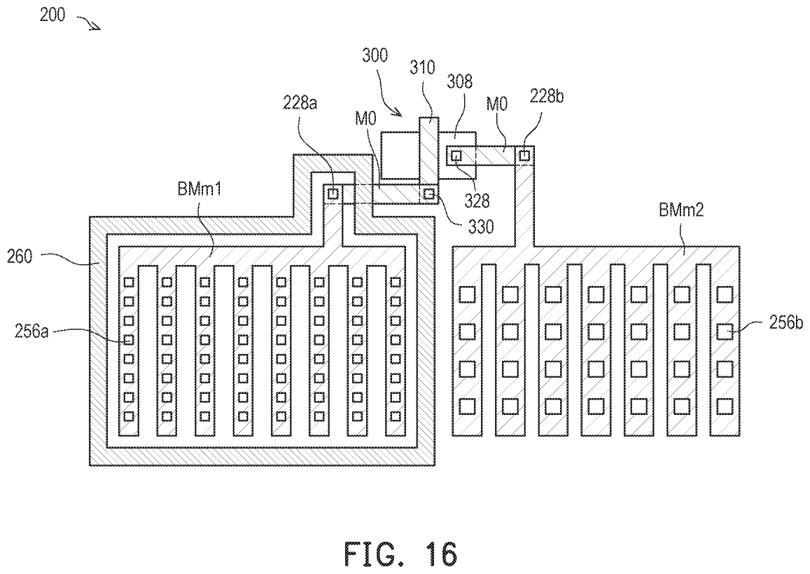

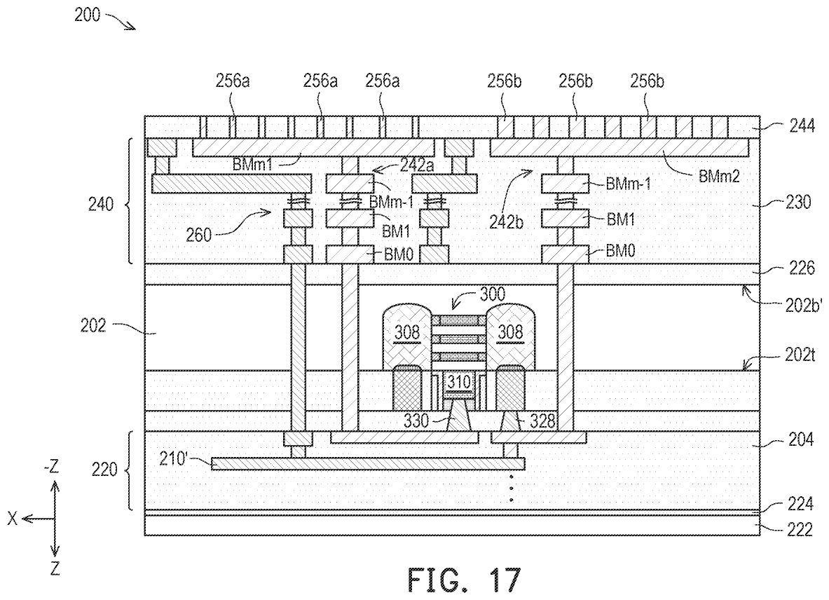

FIG. 16 depicts a fragmentary layout of a first alternative workpiece, and FIG. 17 depicts a fragmentary cross-sectional view of the first alternative workpiece. In the embodiments described with reference to FIGS. 2-15, The shielding plate 210 is implemented to block the transistor 300 from external electromagnetic field related to the RF power source 18. In this alternative embodiment represented by FIGS. 16-17, a Faraday cage 260 is formed to block the transistor 300 from external electromagnetic field related to the RF power source 18. It is noted that only a portion the Faraday cage 260 that is positioned at the same level with the target layer is shown in FIG. 16. The first antenna 242a is surrounded by the Faraday cage 260, when viewed from top, and the Faraday cage 260 may have an opening facing the plasma 20. As represented by FIG. 17, the Faraday cage 260 may include a number of metal lines and vias. A bottom 210′ of the Faraday cage 260 is electrically coupled to the source/drain feature 308 of the transistor 300 and the second antenna 242b.

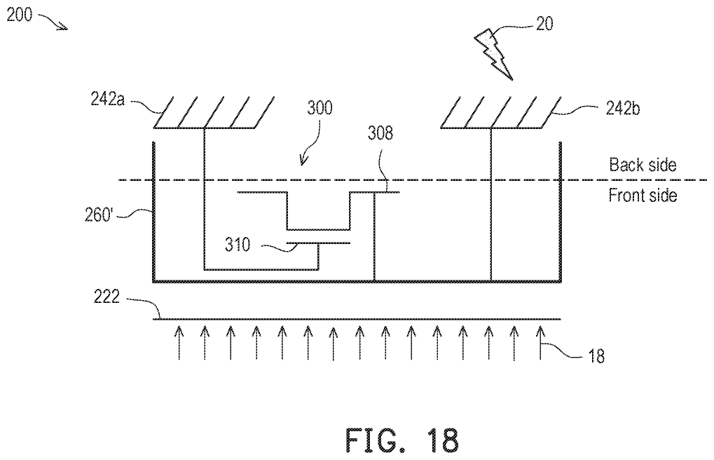

FIG. 18 depicts a simplified schematic diagram of a second alternative workpiece. The second alternative workpiece is similar to the workpiece 200 represented by FIGS. 13-15 and the first alternative workpiece represented by FIGS. 16-17, and one of the differences is that the second alternative workpiece represented by FIG. 18 includes a Faraday cage 260′ that encloses the first antenna 242a, the second antenna 242b, and the transistor 300.

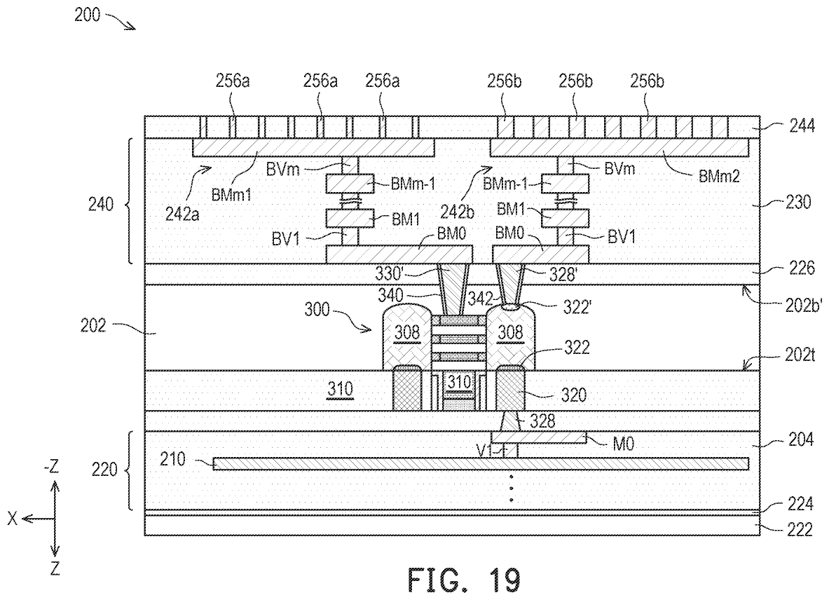

In the above embodiments, the first antenna 242a is electrically coupled to the gate structure 310 of the transistor 300 by a first conductive path 270a (shown in FIG. 14) provided by the first via 228a, the gate via 330 and some conducive features (e.g., the M0 metal line that is in direct contact with the gate via 330) of the FMLI structure 220; the second antenna 242b is electrically coupled to the source/drain feature 308 of the transistor 300 by a second conductive path 270b (shown in FIG. 14) provided by the second via 228b, the source/drain contact via 328, the source/drain contact 320, the silicide layer 322, and some conducive features (e.g., the M0 metal line that is in direct contact with the source/drain contact via 328) of the FMLI structure 220. In some alternative embodiments represented by FIG. 19, the first conductive path 270a may be formed of a gate via 330′ extending through the dielectric layer 226 and the substrate 202 from its bottom surface 202b′, and the second conductive path 270b may be formed of a source/drain via 328′ and a silicide layer 322′. The source/drain via 328′ extends through the dielectric layer 226 and the substrate 202 from its bottom surface 202b′, and the silicide layer 322′ is disposed between the source/drain via 328′ and the source/drain feature 308. The gate via 330′ and the source/drain via 328′ may be isolated from the substrate 202 by a corresponding dielectric barrier layer 340 and 342, respectively. The alternative implementations of the first conductive path 270a and/or second conductive path 270b described with reference to FIG. 19 may be also applied to embodiments described above with reference to FIGS. 16-18. In another alternative embodiment, the first antenna 242a may be electrically coupled to the gate structure 310 by way of the via 228a, the M0 metal line, and the gate via 330, as represented by FIGS. 12-14; and the second antenna 242b may be electrically coupled to the source/drain feature 308 by way of the via 328′, as represented by FIG. 19. In some other alternative embodiments, the first antenna 242a may be electrically coupled to the gate structure 310 by way of the via 330′, as represented by FIG. 19; and the second antenna 242b may be electrically coupled to the source/drain feature 308 by way of the via 228b, the M0 metal line, and the source/drain contact via 328, as represented by FIGS. 12-14.

In the above embodiments described with reference to FIGS. 2-19, structures and methods of reducing plasma process-induced damages are described. In another embodiment, plasma-induced damage are monitored to help determine or set suitable design rules (e.g., antenna rules). FIG. 20 depicts an exemplary method 500 of forming a semiconductor structure 600 to monitor plasma process-induced damages.

Referring to FIGS. 20, 3 and 21, method 500 includes a block 502 where a workpiece 600 is received. The workpiece 600 at block 502 is substantially similar to the workpiece 200 described with reference to FIG. 3, and repeated description is omitted for brevity.

Still referring to FIGS. 20 and 21, method 500 includes a block 504 where source/drain contacts 320, a source/drain contact via 328, and a gate via 330 are formed over the top surface 202t (or front side) of the substrate 202. Operations at block 504 are similar to those in block 104 described with reference to FIG. 3. For this reason, detailed description of operations at block 504 is omitted for brevity.

Referring to FIGS. 20 and 21, method 500 includes a block 506 where a frontside multi-layer interconnect (FMLI) structure 220 is formed over the front side of the substrate 202. Operations of forming the FMLI structure 220 at block 506 are similar to those in block 506 described with reference to FIG. 4. For this reason, detailed description of operations at block 506 is omitted for brevity.

In the present embodiment, operations at block 506 also include forming a field plate 610. The field plate 610 is formed along with the conductive features (e.g., metal lines and/or conducive vias) of the FMLI structure 220. Such configuration would increase the electrical coupling between the source/drain feature 308 and the RF power source 18 during subsequent plasma etching process. To effectively increase the electrical coupling, the field plate 610 is located at one of the upper levels of the metal line layers. For example, in the illustrated embodiment, the field plate 610 is located at the topmost metal line layer Mn of the FMLI structure 220 that is closest to the carrier substrate 222 and is electrically coupled to the source/drain feature 308 by way of the conducive features (e.g., vias V1, . . . . Vn, and metal lines M0, M1, . . . . Mn−1) of the FMLI structure 220 and the source/drain contact via 328, the source/drain contact 320, and the silicide layer 322.

Still referring to FIGS. 20 and 21, method 500 includes a block 508 where the workpiece 600 is bonded to the carrier substrate 222. Operations at block 508 are similar to those in block 108. For this reason, detailed description of operations at block 508 is omitted for brevity. In this embodiment, the field plate 610 and the carrier substrate 222, and dielectric layer(s) disposed therebetween would form a parasitic capacitor that can be charged by the RF power source 18 during subsequent plasma etching processes. The charged parasitic capacitor would affect the electrical potential at the source/drain terminal of the transistor 300, which would thus affect the gate-source cross voltage Vgs between gate terminal and source/drain terminal of the transistor 300.

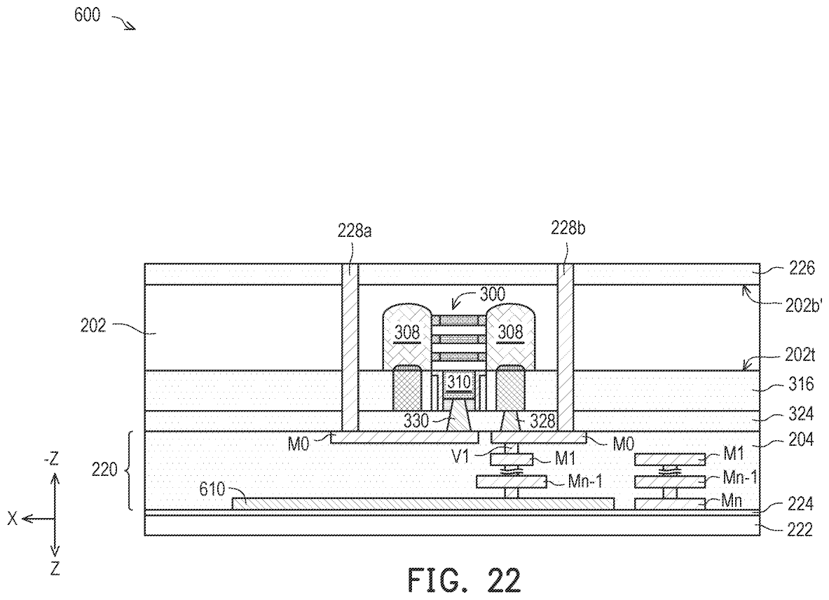

Referring to FIGS. 20 and 22-23, method 100 includes a block 510 where a first conductor structure 242a′ is formed to couple to the gate structure 310 and a second conductor structure 242b′ is formed to couple to one of the source/drain features 308. With reference to FIG. 22, after flipping the workpiece 600 and reducing the thickness of the substrate 202, a dielectric layer 226 is formed on the planarized bottom surface 202b′ of the substrate 202. The dielectric layer 226 may be formed using a deposition process, such as chemical vapor deposition (CVD), physical vapor deposition (PVD), atomic layer deposition (ALD), or other suitable materials. In some embodiments, the dielectric layer 226 may include a dielectric material, such as silicon oxide or silicon nitride.

In the present embodiments, after forming the dielectric layer 226, as shown in FIG. 22, the first via 228a and the second via 228b are formed to electrically couple to the gate structure 310 and the source/drain feature 308, respectively. More specifically, the first via 228a extends through the dielectric layer 226, the substrate 202, and the dielectric structure 316 and the dielectric layer 324 to direct contact the M0 metal line that is in direct contact with the gate via 330; the second via 228b extends through the dielectric layer 226, the substrate 202, and the dielectric structure 316 and the dielectric layer 324 to direct contact the M0 metal line that is in direct contact with the source/drain contact via 328. Although not shown, in some embodiments, a dielectric liner is formed to extend along sidewall of the first via 228a and the second via 228b such that the first and second vias 228a-228b are electrically isolated from the substrate 202.

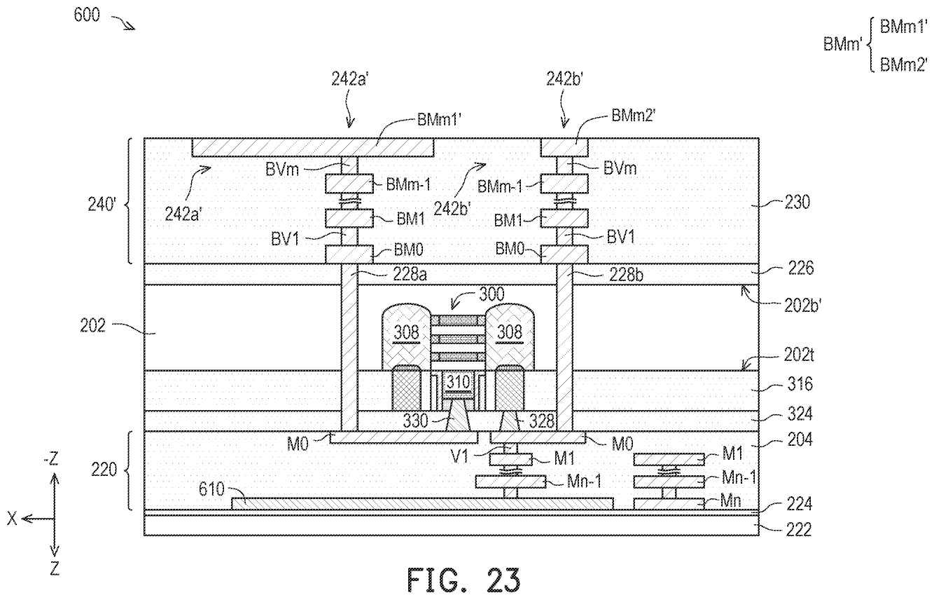

With reference to FIG. 23, a backside multi-layer interconnect (BMLI) structure 240′ is formed over the bottom surface 202b′ of the substrate 202. The backside multi-layer interconnect (BMLI) structure 240′ is substantially similar to the BMLI structure 240 described above with reference to FIG. 6, and one of the differences between the BMLI structure 240′ and the BMLI structure 240 includes that, a target layer (i.e., a metal line layer BMm′ of the BMLI structure 240′) includes metal line BMm1′ electrically coupled to the gate structure 310 of the transistor 300 and metal line BMm2′ electrically coupled to the source/drain feature 308 of the transistor 300. In an embodiment, a width of the metal line BMm1′ is greater than the width BMm2′, such that it would collect and/or accumulate more charged ions during subsequent processes. The metal line BMm1′ and conductive features (i.e., BM0 metal line, BV1 via, BM1 metal line, . . . . BVm via) that couple the metal line BMm1′ to the first via 228a are collectively referred to as a first conductor structure 242a′, and the metal line BMm2′ and conductive features (i.e., BM0 metal line, BV1 via, BM1 metal line, . . . . BVm via) that couple the metal line BMm2 to the second via 228b are collectively referred to as a second conductor structure 242b′. Each of the first conductor structure 242a′ and the second conductor structure 242b′ may function as a corresponding antenna during subsequent fabrication processes (e.g., plasma etching process 250).

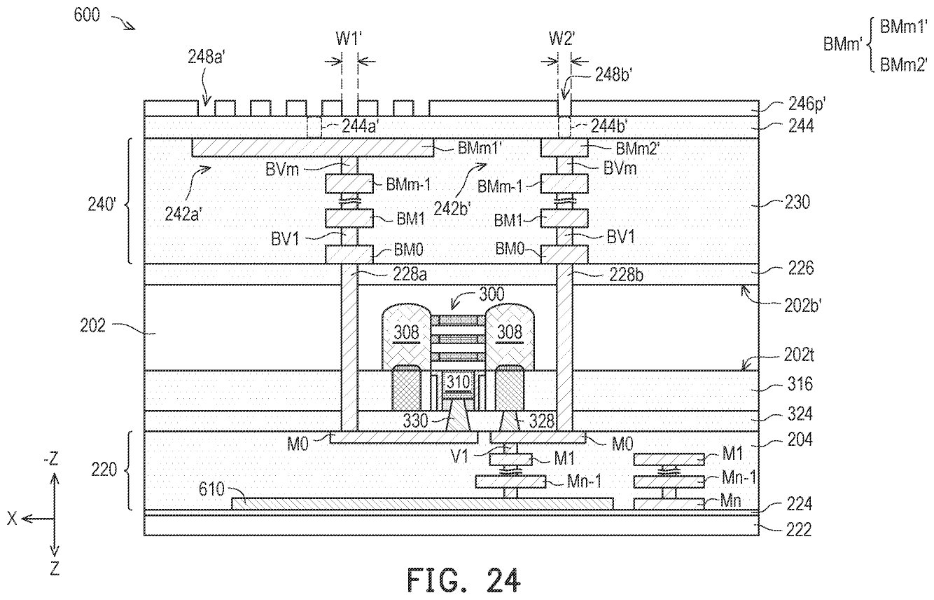

Referring to FIGS. 20 and 24, method 500 includes a block 512 where a dielectric layer 244 is formed over the metal line layer BMm′. The dielectric layer 244 may be formed using a deposition process, such as chemical vapor deposition (CVD), physical vapor deposition (PVD), atomic layer deposition (ALD), or other suitable materials. In some embodiments, the dielectric layer 244 may include a dielectric material, such as silicon oxide or silicon nitride. In other embodiments, the dielectric layer 244 may include a polymer material. In some embodiments, the dielectric layer 244 is a dual-layer structure that includes an interlayer dielectric (ILD) layer formed over an etch stop layer.

Still referring to FIGS. 20 and 24, method 500 includes a block 514 where a patterned mask 246p′ is formed on the dielectric layer 244. The formation of the patterned mask 246p′ is similar to the patterned mask 246p described above with reference to FIGS. 8-9 and repeated description is omitted for reason of simplicity. The differences between the patterned mask 246p′ and the patterned mask 246p include that, the patterned mask 246p′ includes first openings 248a′ and a second opening 248b′ exposing portions of the dielectric layer 244. In the present embodiment, each of the first openings 248a′ exposes a first portion (e.g., 244a′) of the dielectric layer 244 thereunder, and the second opening 248b exposes a second portion (e.g., 244b′) of the dielectric layer 244, and when viewed from top, the area of the first portion 244a′ of the dielectric layer 244 is greater than the area of the second portion 244b′ of the dielectric layer 244. In an embodiment, the first opening 248a′ spans a width W1′ along the X direction, the second opening 248b′ spans a width W2′ along the X direction, and the width W1′ is greater than the width W2′.

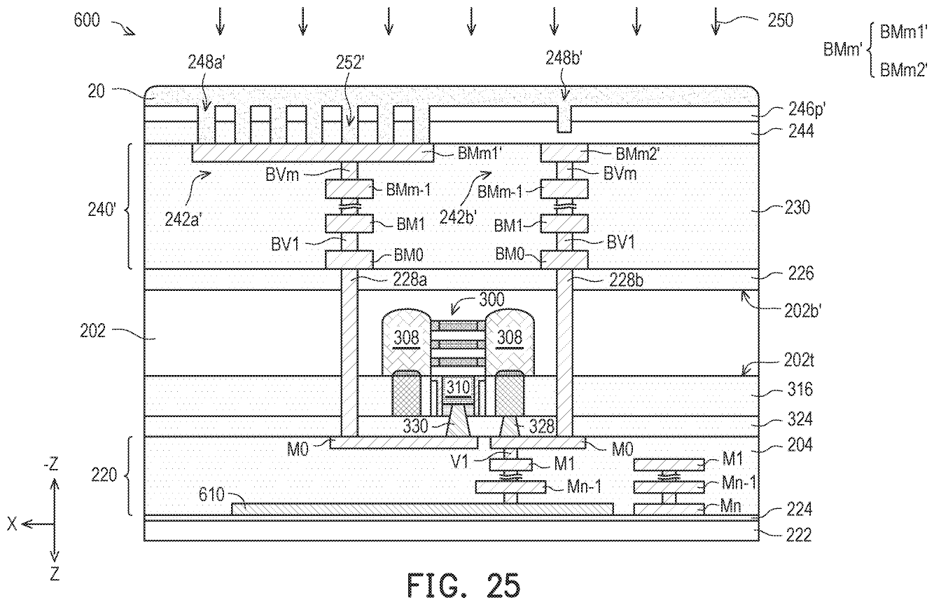

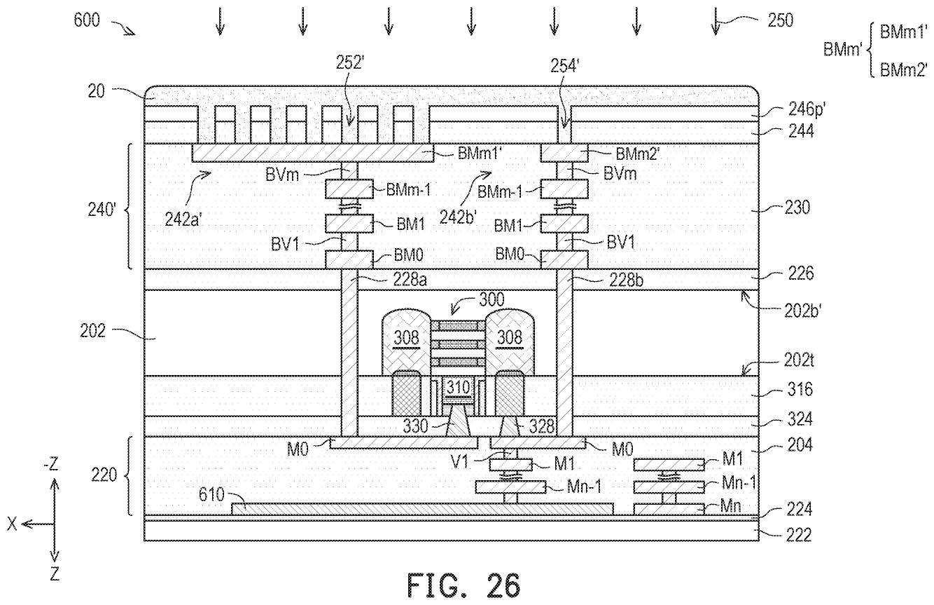

Referring to FIGS. 20 and 25-27, method 500 includes a block 516 where a plasma etching process 250 is performed to form first trenches and a second trench in the dielectric layer 244. After forming the patterned mask 246p′, the workpiece 600 is placed into the apparatus 10 to undergo the plasma etching process 250. As illustrated by FIG. 25, surfaces of the patterned mask 246p′ and top surfaces of the first and second portions (e.g., 244a′, 244b′) of the dielectric layer 244 are exposed in the plasma environment. After performing the plasma etching process 250 for a first duration TI′ of time, as represented by FIG. 25, the first portions 244a′ of the dielectric layer 244 exposed by the first openings 248a′ are substantially removed to form first trenches 252′ (filled by plasma 20) exposing portions of the metal line BMm1′ thereunder, while the second portion 244b′ of the dielectric layer 244 exposed by the second openings 248b′ is only partially removed. That is, after the first duration TI′ of time, the metal line BMm2′ has not been exposed to the plasma 20. Put differently, the plasma etching process 250 etches the first portion 244a′ at a first etch rate and etches the second portion 244b′ at a second etch rate that is lower than the first etch rate. The different etch rates are related to the configurations (e.g., widths) of the first openings 248a′ and the second opening 248b′. More specifically, for features with different dimensions etched simultaneously, the aspect ratio dependent etching (ARDE) effect causes bigger features (e.g., the first portions 244a′) to be etched at faster rates. With the continuously performing of plasma etching process 250, as represented by FIG. 26, the second portion 244b′ of the dielectric layer 244 exposed by the second openings 248b′ is fully removed, thereby forming a second trench 254′ exposing a portion of the metal line BMm2′ thereunder. That is, the first trenches 252′ are formed earlier than the second trench 254′. Each of the first trenches 252′ has a width (e.g., W1′) greater than the width (e.g., W2′) of the second trench 254′. The performing of the plasma etching process 250 may be stopped upon formation of the second trench 254′, and the patterned mask 246p′ may be then selectively removed.

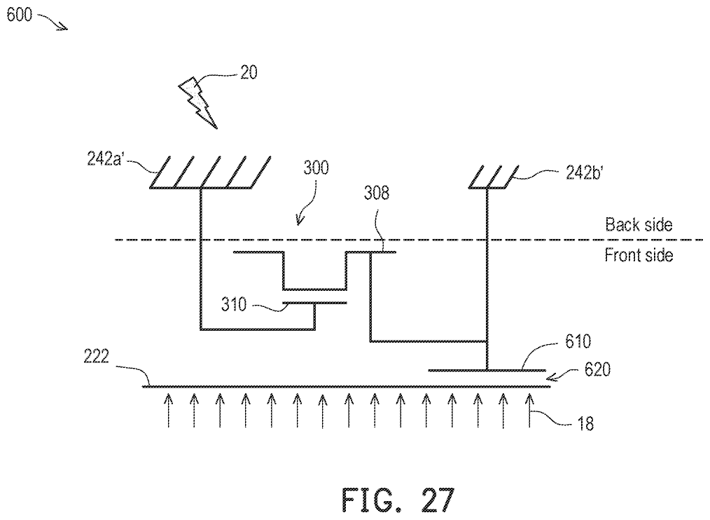

Forming the first and the second trenches 252′ and 254′ in this chronological order allows proper PID risk assessment. As described above, the first trench 252′ is formed earlier than the second trench 254′, and more charged ions will be collected and accumulated by the first antenna 242a′ than the second antenna 242b′. In an embodiment, a density (i.e., the quantity per unit volume) of the first trenches 252′ is greater than the density of the second trenches 254′. For example, as illustrated, the workpiece 600 may include one second trench 254′. FIG. 27 depicts a simplified schematic diagram of the workpiece 600 shown in FIG. 26. The first antenna 242a′ that is electrically coupled to the gate terminal of the transistor 300 is turned on earlier than the second antenna 242b′ that is electrically coupled to the source/drain terminal of the transistor 300. In other words, the gate structure 310 of the transistor 300 will be exposed to the accumulated charges first, which contributes to the proper evaluation of the reliability of the transistor 300. The field plate 610 and the carrier substrate 222 contributes to a parasitic capacitor 620. This parasitic capacitor 620 may capacitively couple the electrical field of the RF power source 18 to the source/drain feature 308 to increase the gate-source cross voltage Vgs between gate terminal and source/drain terminal of the transistor 300, thereby providing a higher voltage stress to the transistor 300. Thus, the reliability of the transistor 300 may be more accurately evaluated.

Referring to FIGS. 20 and 28-29, method 500 includes a block 518 where vias 256a′ and via 256b′ are formed in the first trenches 252′ and second trench 254′, respectively. The vias 256a′ and vias 256b′ track the shapes of the first trenches 252′ and second trench 254′, respectively. That is, each of the vias 256a′ has the width W1′, and the via 256b′ has the width W2′ that is less than the width W1′. The composition and formation of the vias 256a′ and 256b′ are similar to those of the vias 256a′ and 256b′, and repeated description is omitted for brevity.

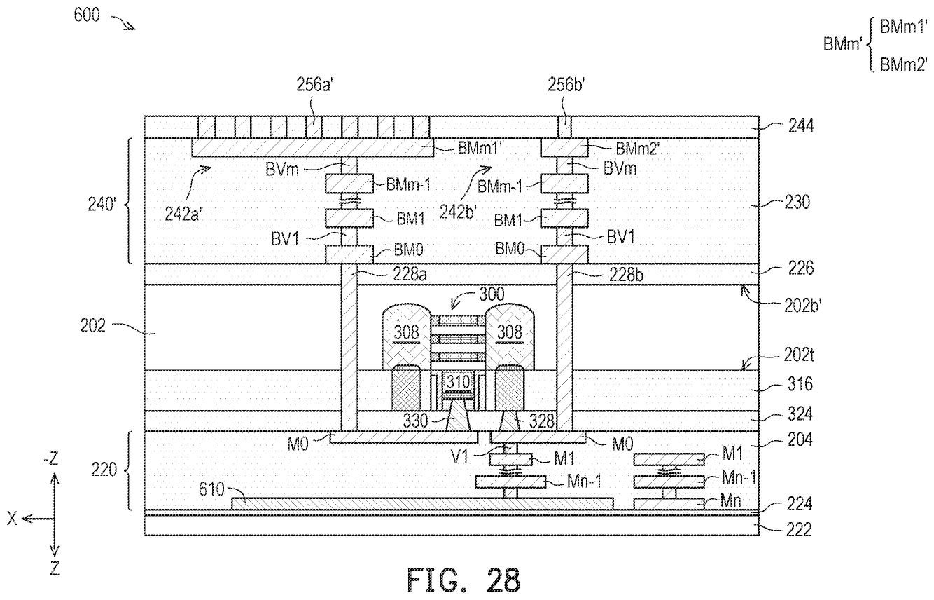

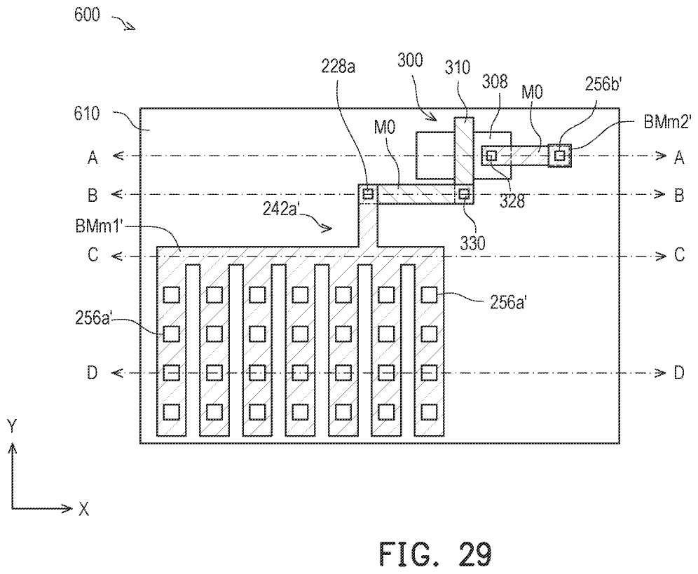

FIG. 29 depicts a fragmentary layout of the workpiece 600 shown in FIG. 28. Some features are omitted in FIG. 29 for brevity. The fragmentary cross-sectional view shown in FIG. 28 may be a composite cross-sectional view of the workpiece 600 which is a combination of the fragmentary cross-sectional views taken along line A-A, line B-B, line C-C, and line D-D shown in FIG. 29. In the present embodiments, when viewed from top, the metal line BMm1′ has a single-sided comb-like structure. It is understood that the metal line BMm1′ may have other suitable profiles (e.g., double-sided comb-like structure, a rectangular shape). In an embodiment, when viewed from top, the area of the metal line BMm1′ is greater than the area of the metal line BMm2′ such that the metal line BMm1′ may collect more charges from the charged ions in the plasma 20. The first and second antenna structures 242a′-242b′ and/or the vias 256a′-256b′ may be placed in scribe lines or in dies.

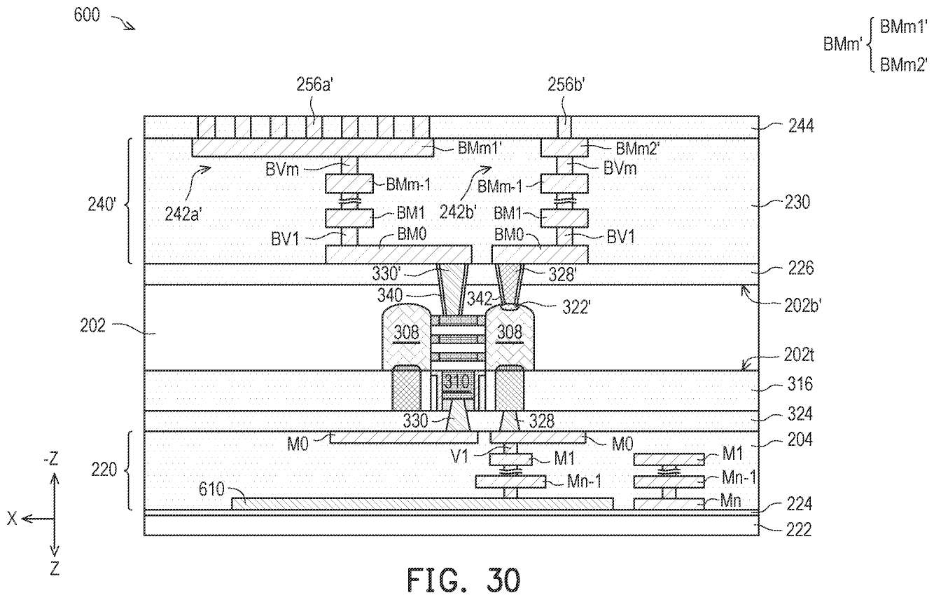

In the above embodiments, the first antenna 242a′ is electrically coupled to the gate structure 310 of the transistor 300 by the first conductive path 270a provided by the first via 228a, the gate via 330 and conducive features (e.g., the M0 metal line that is in direct contact with the gate via 330) of the FMLI structure 220; the second antenna 242b′ is electrically coupled to the source/drain feature 308 of the transistor 300 by the second conductive path 270b provided by the second via 228b, the source/drain contact via 328, the source/drain contact 320, the silicide layer 322, and conducive features (e.g., the M0 metal line that is in direct contact with the source/drain contact via 328) of the FMLI structure 220. In some alternative embodiments represented by FIG. 30, the first conductive path may be provided by a gate via 330′ extending through the dielectric layer 226 and the substrate 202 from its bottom surface 202b′, and the second conductive path may be provided by a source/drain via 328′ and a silicide layer 322′. The source/drain via 328′ extends through the dielectric layer 226 and the substrate 202 from its bottom surface 202b′, and the silicide layer 322′ is disposed between the source/drain via 328′ and the source/drain feature 308. The gate via 330′ and the source/drain via 328′ may be isolated from the substrate 202 by a corresponding dielectric barrier layer 340 and 342, respectively.

FIG. 31 depicts a simplified equivalent circuit diagram 700 of the semiconductor structure 200 and semiconductor structure 600 described above with reference to FIGS. 1-30. During the performing of the plasma etching process 250, the transistor 300 may be regarded as a two-terminal device having a first terminal A and a second terminal B, the electrical potential associated with the charged ions in the plasma 20 will be regarded as a voltage source Vₚₗₐₛₘₐ, and the electrical potential associated with the RF power source 18 will be regarded as a RF signal V_{RF}.

The circuit diagram also includes a resistor R₁ having two ends. The resistor R₁ represents a parasitic resistance of the first conductive path 270a described above, and one end of the resistor R₁ is electrically coupled to a switch SW₁, the other end of the resistor R₁ is electrically coupled to the first terminal A of the transistor 300. The circuit diagram also includes a resistor R₂ having two ends. The resistor R₂ represents a parasitic resistance of the second conductive path 270b described above, and one end of the resistor R₂ is electrically coupled to a switch SW₂, the other end of the resistor R₂ is electrically coupled to the second terminal B of the transistor 300. The switch SW₁ and switch SW₂ are also electrically coupled to the voltage source Vₚₗₐₛₘₐ. In the present embodiments, the switch SW₁ analogies the status of the formation of the trench 254 (shown in FIG. 12) or trench 252′ (shown in FIG. 25), and the switch SW₂ analogies the status of the formation of the trench 252 (shown in FIG. 11) or trench 254′ (shown in FIG. 26). More specifically, when the trench 254/252′ is formed, the switch SW₁ is deemed as turned on, and when the trench 252/254′ is formed, the switch SW₂ is deemed as turned on.

The circuit diagram also includes a capacitor C₁ coupled to both the RF signal V_{RF} and the first terminal A of the transistor 300, a capacitor C₂ coupled to both the RF signal and the second terminal B of the transistor 300, and a capacitor C₃ coupled to both the first terminal A and the second terminal B of the transistor 300. In the present embodiments, the capacitor C₁ represents the coupling capacitance associated with the first antenna 242a/242a′ and the carrier substrate 222, the capacitor C₂ represents a combination of the coupling capacitance associated with the second antenna 242b/242b′ and the carrier substrate 222 and the coupling capacitance associated with the field plate 610 and the carrier substrate 222, and the capacitor C₃ represents a gate capacitive effect capacitance Cox.

The transistor 300 is forced to couple to the voltage source Vₚₗₐₛₘₐ during the performing of the plasma etching process 250. In this present disclosure, sequential order of the terminal A and terminal B of the transistor 300 being connected to the voltage source Vₚₗₐₛₘₐ may be chosen based on the purpose of the semiconductor structure. For example, to protect the transistor 300 from being damaged by PID, it is desired to reduce the voltage difference between terminal A and terminal B. Therefore, the switch SW₂ will be turned on earlier than the switch SW₁. In another aspect, to perform proper PID assessment, it is desired to increase the voltage difference between terminal A and terminal B. Therefore, the switch SW₁ will be turned on earlier than the switch SW₂. Resistances of the resistors R₁ and R₂ and capacitances of the capacitors C₁, C₂, and C₃ may also be adjusted (e.g., by forming the field plate 610 or the shielding plate 210) accordingly to achieve those goals.

The present disclosure provides for many different embodiments. Semiconductor structures and methods of fabrication thereof are disclosed herein. In one exemplary aspect, the present disclosure is directed to a method. The method includes forming a first antenna coupled to a gate structure of a transistor, the first antenna comprising a first metal line, forming a second antenna coupled to a source/drain feature of the transistor, the second antenna comprising a second metal line, wherein the first metal line and the second metal line are disposed within a same metallization layer, forming a dielectric layer over the metallization layer, performing a plasma etching process to the dielectric layer, thereby forming first trenches exposing the first metal line and second trenches exposing the second metal line, respectively, wherein the first trenches and second trenches are formed in a chronological order, and forming first conductive vias and second conductive vias in the first trenches and second trenches, respectively. In some embodiments, a via of the first conductive vias spans a first width, and a via of the second conductive vias spans a second width greater than the first width. In some embodiments, the second trenches may be formed earlier than the first trenches. In some embodiments, the method may also include, before the performing of the plasma etching process, forming a patterned mask layer on the dielectric layer, wherein the patterned mask layer comprises first openings disposed directly over the first metal line and second openings disposed directly over the second metal line, wherein a width of one of the second openings may be greater than a width of one of the first openings. In some embodiments, the plasma etching process etches a portion of the dielectric layer exposed by the first openings at a first rate and etches a portion of the dielectric layer exposed by the second openings at a second rate greater than the first rate. In some embodiments, the metallization layer may be disposed under the gate structure of the transistor. In some embodiments, the method may also include, forming a shielding plate over the gate structure of the transistor and electrically coupled to the source/drain feature of the transistor. In some embodiments, the method may also include, forming a conductive cage surrounding the first antenna, wherein the conducive cage comprises a sidewall disposed adjacent to the first antenna and a bottom electrically coupled to the source/drain feature of the transistor. In some embodiments, a density of the first conductive vias may be greater than a density of the second conductive vias. In some embodiments, each of the first and second antennas further may include vias and metal lines disposed between the metallization layer and the transistor.

In another exemplary aspect, the present disclosure is directed to a method. The method includes receiving a workpiece comprising a transistor comprising a gate structure and a source/drain feature adjacent to the gate structure, and a first conductive feature and a second conductive feature disposed in a first dielectric layer, wherein the source/drain feature is coupled to the first conductive feature by way of a first conductive path, and the gate structure is coupled to the second conductive feature by way of a second conductive path. The method also includes forming a second dielectric layer on the first and second conductive features, forming a patterned mask over the second dielectric layer, the patterned mask comprising a first opening disposed directly over the first conductive feature and a second opening disposed directly over the second conductive feature and smaller than the first opening, by using the patterned mask as an etch mask, performing a plasma etching process to etch the second dielectric layer to form a first trench exposing the first conductive feature and a second trench exposing the second conductive feature, and forming a first conductive via in the first trench and a second conductive via in the second trenches. In some embodiments, the first trench and the second trench may be formed in a chronological order. In some embodiments, upon formation of the first trench, a depth of the second trench may be less than a depth of the first trench. In some embodiments, upon completion of the performing of the plasma etching process, the second trench and the first trench may have a same depth. In some embodiments, the first conductive feature and the second conducive feature are disposed under the gate structure of the transistor, wherein the workpiece may also include a shielding plate disposed over the gate structure of the transistor and electrically coupled to the source/drain feature of the transistor. In some embodiments, the transistor may include a plurality of nanostructures disposed over the first conductive feature and the second conducive feature, and the gate structure wraps around each nanostructure of the plurality of nanostructures.

In yet another exemplary aspect, the present disclosure is directed to a semiconductor structure. The semiconductor structure includes a transistor comprising a plurality of nanostructures, a gate structure wrapping around and over each of the plurality of nanostructures, and a source/drain feature coupled to each of the plurality of nanostructures. The semiconductor structure also includes a first antenna coupled to the gate structure, first vias under and in direct contact with the first antenna, a second antenna coupled to the source/drain feature, second vias under and in direct contact with the second antenna, wherein, when viewed from top, a width of the second vias is greater than a width of the first vias. In some embodiments, each of the first antenna and the second antenna comprises a plurality of vias and metal lines disposed under the gate structure. In some embodiments, the semiconductor structure may also include a conductive shielding plate disposed over the transistor and electrically coupled to the source/drain feature. In some embodiments, a density of the first vias is greater than a density of the second vias.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first antenna coupled to a gate structure of a transistor, the first antenna comprising a first metal line;
forming a second antenna coupled to a source/drain feature of the transistor, the second antenna comprising a second metal line, wherein the first metal line and the second metal line are disposed within a same metallization layer;
forming a dielectric layer over the metallization layer;
performing a plasma etching process to the dielectric layer, thereby forming first trenches exposing the first metal line and second trenches exposing the second metal line, respectively, wherein the first trenches and second trenches are formed in a chronological order; and
forming first conductive vias and second conductive vias in the first trenches and second trenches, respectively.

2. The method of claim 1, wherein a via of the first conductive vias spans a first width, and a via of the second conductive vias spans a second width greater than the first width.

3. The method of claim 1, wherein the second trenches are formed earlier than the first trenches.

4. The method of claim 1, further comprising:
before the performing of the plasma etching process, forming a patterned mask layer on the dielectric layer, wherein the patterned mask layer comprises first openings disposed directly over the first metal line and second openings disposed directly over the second metal line, wherein a width of one of the second openings is greater than a width of one of the first openings.

5. The method of claim 4, wherein the plasma etching process etches a portion of the dielectric layer exposed by the first openings at a first rate and etches a portion of the dielectric layer exposed by the second openings at a second rate greater than the first rate.

6. The method of claim 1, wherein the metallization layer is disposed under the gate structure of the transistor.

7. The method of claim 6, further comprising: forming a shielding plate over the gate structure of the transistor and electrically coupled to the source/drain feature of the transistor.

8. The method of claim 6, further comprising: forming a conductive cage surrounding the first antenna, wherein the conducive cage comprises a sidewall disposed adjacent to the first antenna and a bottom electrically coupled to the source/drain feature of the transistor.

9. The method of claim 1, wherein a density of the first conductive vias is greater than a density of the second conductive vias.

10. The method of claim 1, wherein each of the first and second antennas further comprises vias and metal lines disposed between the metallization layer and the transistor.

11. A method, comprising:
receiving a workpiece comprising:
a transistor comprising a gate structure and a source/drain feature adjacent to the gate structure, and
a first conductive feature and a second conductive feature disposed in a first dielectric layer, wherein the source/drain feature is coupled to the first conductive feature by way of a first conductive path, and the gate structure is coupled to the second conductive feature by way of a second conductive path;
forming a second dielectric layer on the first and second conductive features;
forming a patterned mask over the second dielectric layer, the patterned mask comprising a first opening disposed directly over the first conductive feature and a second opening disposed directly over the second conductive feature and smaller than the first opening;
by using the patterned mask as an etch mask, performing a plasma etching process to etch the second dielectric layer to form a first trench exposing the first conductive feature and a second trench exposing the second conductive feature; and
forming a first conductive via in the first trench and a second conductive via in the second trenches.

12. The method of claim 11, wherein the first trench and the second trench are formed in a chronological order.

13. The method of claim 11, wherein upon formation of the first trench, a depth of the second trench is less than a depth of the first trench.

14. The method of claim 13, wherein upon completion of the performing of the plasma etching process, the second trench and the first trench have a same depth.

15. The method of claim 11, wherein the first conductive feature and the second conducive feature are disposed under the gate structure of the transistor, wherein the workpiece further comprises a shielding plate disposed over the gate structure of the transistor and electrically coupled to the source/drain feature of the transistor.

16. The method of claim 11, wherein the transistor comprises a plurality of nanostructures disposed over the first conductive feature and the second conducive feature, and the gate structure wraps around each nanostructure of the plurality of nanostructures.

17. A semiconductor structure, comprising:
a transistor comprising:
a plurality of nanostructures,
a gate structure wrapping around and over each of the plurality of nanostructures, and,
a source/drain feature coupled to each of the plurality of nanostructures;
a first antenna coupled to the gate structure;
first vias under and in direct contact with the first antenna;
a second antenna coupled to the source/drain feature;
second vias under and in direct contact with the second antenna, wherein, when viewed from top, a width of the second vias is greater than a width of the first vias.

18. The semiconductor structure of claim 17, wherein each of the first antenna and the second antenna comprises a plurality of vias and metal lines disposed under the gate structure.

19. The semiconductor structure of claim 17, further comprising: a conductive shielding plate disposed over the transistor and electrically coupled to the source/drain feature.

20. The semiconductor structure of claim 17, wherein a density of the first vias is greater than a density of the second vias.
